(19) United States
(12) Patent Application Publication
(10) Pub. No.: US 2026/0271298 A1
(43) Pub. Date: Sep. 10, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Donggun Kim, Suwon-si (KR); MinKyung Kim, Suwon-si (KR); Eun-Young Lee, Suwon-si (KR)

(73) Assignee: Samsung Electronics Co., Ltd., Suwon-si (KR)

(21) Appl. No.: 19/330,026

(22) Filed: Sep. 16, 2025

(30) Foreign Application Priority Data
Mar. 6, 2025 (KR) 10-2025-0029323

(51) Int. Cl. H10B 43/40; H10B 41/27; H10B 41/35; H10B 41/41; H10B 43/27; H10B 43/35

(52) U.S. Cl. CPC H10B 43/40; H10B 41/27; H10B 41/35; H10B 41/41; H10B 43/27; H10B 43/35

(57) ABSTRACT

A semiconductor device according to embodiments includes a substrate, and a plurality of transistors on or at the substrate. The plurality of transistors include a first conductivity type transistor. The first conductivity type transistor includes a gate insulation layer, a first intermediate layer, and a gate electrode sequentially on the substrate. The first intermediate layer includes a first region including a first metal on the gate insulation layer and a second region spaced apart from the gate insulation layer on the first region. The second region includes the first metal, and a second metal different from the first metal.

### CROSS-REFERENCE TO RELATED APPLICATIONS

This present application claims priority to and the benefit of Korean Patent Application No. 10-2025-0029323 filed on Mar. 6, 2025 with the Korean Intellectual Property Office, the entire disclosure of which is incorporated herein by reference.

### FIELD

The present disclosure relates to a semiconductor device and an electronic system including the same.

### BACKGROUND

A semiconductor device may have a small size while performing various functions, and is thus widely used in various electronic industries. As advancements are made in the electronic industry, research on improving performance of a semiconductor device has continued. For example, performance and reliability of the semiconductor device may be improved by improving performance and reliability of a plurality of circuit elements included in the semiconductor device.

### SUMMARY

The present disclosure attempts to provide a semiconductor device having improved performance and reliability, and an electronic system including the same.

A semiconductor device according to embodiments includes a substrate, and a plurality of transistors on or at the substrate. The plurality of transistors include a first conductivity type transistor. The first conductivity type transistor includes a gate insulation layer, a first intermediate layer, and a gate electrode sequentially on the substrate. The first intermediate layer includes a first region including a first metal on the gate insulation layer and a second region spaced apart from the gate insulation layer on the first region. The second region includes the first metal, and a second metal different from the first metal.

A semiconductor device according to embodiments includes a substrate, and a plurality of transistors on or at the substrate. The plurality of transistors include a first conductivity type transistor. The first conductivity type transistor includes a gate insulation layer, a first intermediate layer, and a gate electrode sequentially on the substrate. The first intermediate layer includes a first layer and a second layer sequentially on the gate insulation layer and including different materials. The first layer includes an oxygen-amount change region in which an oxygen amount changes. In a thickness direction of the first layer, the oxygen-amount change region is partially disposed in the first layer to be adjacent to a first surface of the first layer that is adjacent to the second layer and to be spaced apart from the gate insulation layer.

An electronic system according to embodiments includes a main substrate, a semiconductor device on the main substrate, and a controller electrically connected to the semiconductor device on the main substrate. The semiconductor device includes a substrate and a plurality of transistors on or at the substrate. The plurality of transistors include a first conductivity type transistor. The first conductivity type transistor includes a gate insulation layer, a first intermediate layer, and a gate electrode sequentially on the substrate. The first intermediate layer includes a first region including first metal on the gate insulation layer and a second region spaced apart from the gate insulation layer on the first region. The second region includes the first metal, and a second metal different from the first metal.

A manufacturing method of a semiconductor device according to embodiments includes forming a plurality of transistors on or at a substrate. The plurality of transistors include a first conductivity type transistor in a first transistor region and a second conductivity type transistor in a second transistor region.

The forming of the plurality of transistors include forming a first gate insulation layer and a preliminary layer including a first metal on the substrate in the first and second transistor regions, forming a first layer by doping a second metal different from the first metal to an upper portion of the preliminary layer in a thickness direction of the preliminary layer in the first and second transistor regions, removing a portion of the first layer in the second transistor region, forming a second layer and a gate electrode on the first gate insulation layer and the first layer in the first and second transistor regions, and pattering the first gate insulation layer, the first layer, the second layer, and the gate electrode to form gate structures of the first and second conductivity type transistors.

In the process of forming the first layer, the second metal may be doped by an ion implantation process.

In the process of forming the preliminary layer, in the first and second transistor regions, the preliminary layer may be in contact with the first gate insulation layer.

Each of the first and second conductivity type transistor may have a high dielectric constant metal gate structure.

The preliminary layer may include the first metal and oxygen, and the second metal may have an oxygen areal density different from an oxygen areal density of the first metal.

The second metal may include at least one of a group 2 element, a transition metal, a group 13 element, a group 14 element, and a group 15 element. For example, the second metal may include at least one of strontium, yttrium, titanium, zirconium, hafnium, niobium, and germanium.

The process of removing the portion of the first layer may be performed by a wet etching process.

According to embodiments, a first layer of a first intermediate layer may include a first region including a first metal and a second region including a second metal, which is different from the first metal, in a first conductivity type transistor, and a threshold voltage of the first conductivity type transistor may be reduced. The second region may be spaced apart from a first gate insulation layer while interposing the first region therebetween, and a process of forming the second region or the second metal may be prevented from affecting the first gate insulation layer. A second intermediate layer may include a second layer without the first layer in the second conductivity type transistor, and a threshold voltage of the second conductivity type transistor may be reduced. Further, a height difference between a plurality of transistors may be reduced and a margin in an etching process may be improved.

Thereby, performance and reliability of a plurality of transistors may be improved, and performance and reliability of a semiconductor device may be improved.

### BRIEF DESCRIPTION OF THE DRAWINGS

FIG. 1 is a partial cross-sectional view schematically illustrating a semiconductor device according to embodiments.

FIG. 2 is an enlarged cross-sectional view illustrating an example of a channel structure that is included in the semiconductor device illustrated in FIG. 1.

FIG. 3 is an enlarged cross-sectional view of a portion A in FIG. 1.

FIG. 4 is an enlarged cross-sectional view of a portion B and a portion C in FIG. 3.

FIG. 5 is an enlarged cross-sectional view of an example of a portion D in FIG. 4.

FIG. 6 is a graph schematically illustrating an example of amounts of second metal and oxygen in a direction E in FIG. 5.

FIG. 7 is a graph schematically illustrating an example of amounts of second metal and oxygen in a direction E in FIG. 5.

FIG. 8 is an enlarged cross-sectional view of an example of a portion D in FIG. 4.

FIG. 9 is a graph schematically illustrating amounts of second metal and oxygen in a direction F in FIG. 8.

FIG. 10 to FIG. 14 are cross-sectional views illustrating a manufacturing method of a semiconductor device according to embodiments.

FIG. 15 is a partial cross-sectional view schematically illustrating a semiconductor device according to embodiments.

FIG. 16 schematically illustrates an electronic system that includes a semiconductor device according to embodiments.

FIG. 17 is a perspective view schematically illustrating an electronic system including a semiconductor device according to embodiments.

FIG. 18 is a cross-sectional view schematically illustrating a semiconductor package according to embodiments.

FIG. 19 is a cross-sectional view schematically illustrating a semiconductor package according to embodiments.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiments provided herein.

A portion unrelated to the description is omitted in order to clearly describe the present disclosure, and the same or similar components are denoted by the same reference numeral throughout the present specification.

Further, since a size and/or a thickness of a portion, a region, a member, a unit, a layer, a film, a substrate, or so on illustrated in the accompanying drawings may be arbitrarily illustrated for better understanding and convenience of explanation, the present disclosure is not limited to the illustrated size and/or thickness. In the drawings, thicknesses of a portion, a region, a member, a unit, a layer, a film, a substrate, or so on may be enlarged or exaggerated for convenience of explanation and/or simple illustration.

It will be understood that when a component such as a portion, a region, a member, a unit, a layer, a film, a substrate, or so on is referred to as being “on” or “above” another component, it may be directly on or above another component or an intervening component may also be present. In contrast, when a component is referred to as being “directly on” or “directly above” another component, there is no intervening component present. Further, when a component is referred to as being “on” or “above” a reference component, a component may be disposed on, above, or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

plan view”, or “in a plan view” may indicate a case where a portion is viewed from above or a top portion, and a phrase “on a cross-section”, “in a cross-section”, “on a cross-sectional view”, or “in a cross-sectional view” may indicate a vertical cross-sectional view from a side.

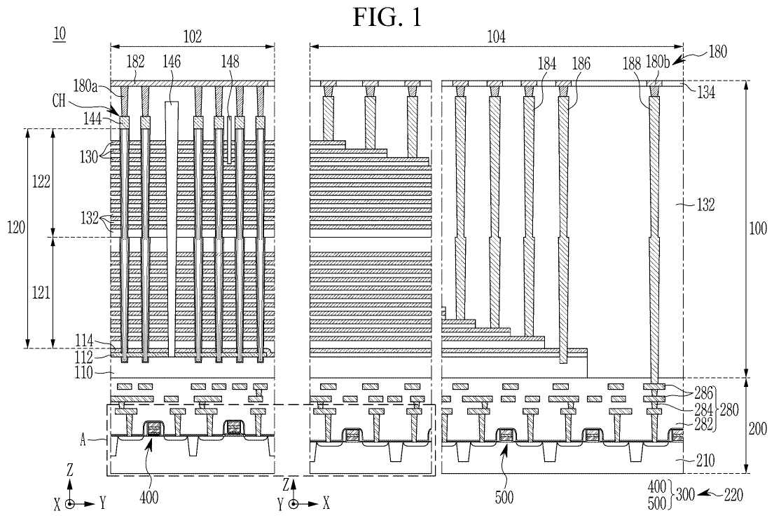

Hereinafter, referring to FIG. 1 to FIG. 14, a semiconductor device according to embodiments and a manufacturing method of the same will be described in detail.

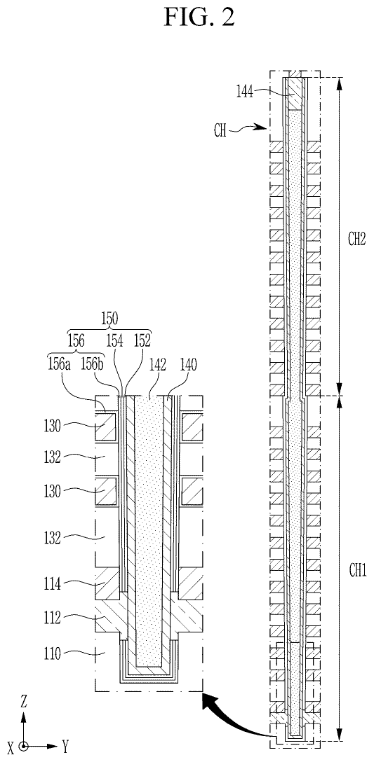

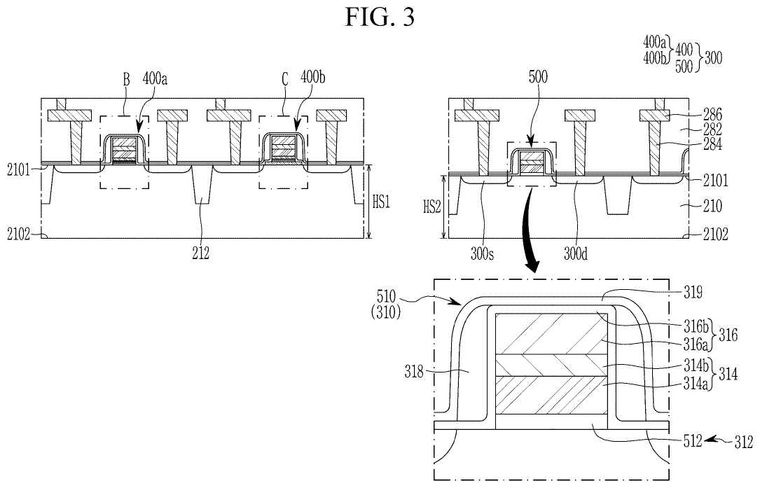

FIG. 1 is a partial cross-sectional view schematically illustrating a semiconductor device 10 according to embodiments. FIG. 2 is an enlarged cross-sectional view illustrating an example of a channel structure CH included in the semiconductor device 10 illustrated in FIG. 1. Coordinates of FIG. 1 relate to a cell region 100. FIG. 1 illustrates a cross-sectional view of a portion of a circuit region 200 where a gate structure 310 (refer to FIG. 3) and source and drain regions 300s and 300d (refer to FIG. 3) are disposed together regardless of the coordinates of FIG. 1.

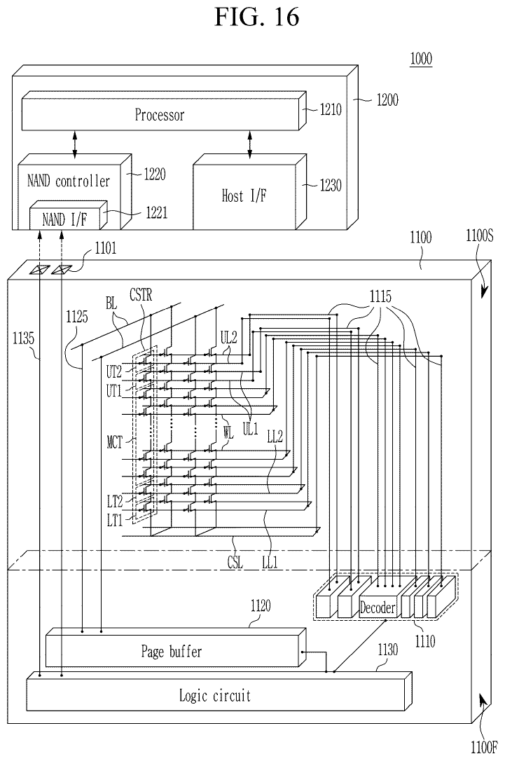

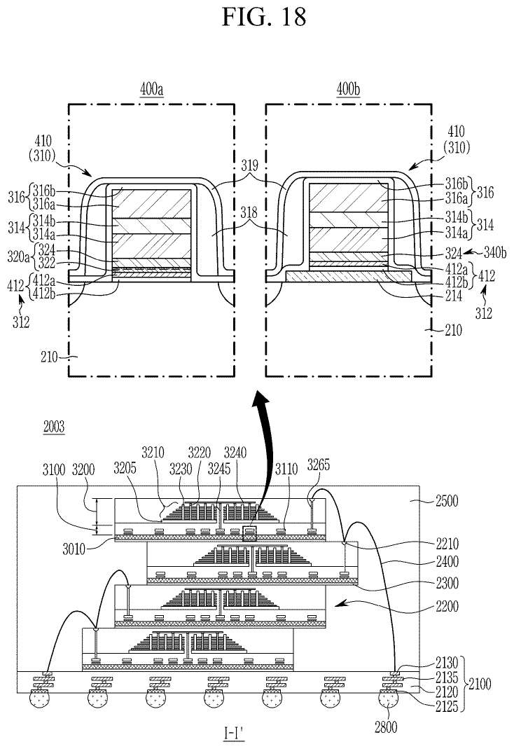

Referring to FIG. 1 and FIG. 2, a semiconductor device 10 according to embodiments may include a cell region 100 that includes a memory cell structure and a circuit region 200 that includes a peripheral circuit structure controlling an operation of the memory cell structure. For example, the circuit region 200 and the cell region 100 may correspond to a first structure 1100F and a second structure 1100S of a semiconductor device 1100 included in an electronic system 1000 illustrated in FIG. 16, respectively. For example, the circuit region 200 and the cell region 100 may be portions including a first structure 3100 and a second structure 3200 of a semiconductor device 2200 illustrated in FIG. 18, respectively.

The circuit region 200 may include a peripheral circuit structure on a first substrate 210, and the cell region 100 may include a gate stacking structure 120 and a channel structure CH as a memory cell structure on a second substrate 110. The circuit region 200 may include a first wiring portion 280, and the cell region 100 may include a second wiring portion 180 electrically connected to the memory cell structure.

In embodiments, the cell region 100 may be disposed on the circuit region 200. Accordingly, an area corresponding to the circuit region 200 does not need to be secured separately from the cell region 100. Therefore, an area of the semiconductor device 10 may be reduced. However, the embodiments are not limited thereto, and the circuit region 200 may be disposed next to the cell region 100. Other various modified embodiments are possible.

The cell region 100 may include a cell array region 102 and a connection region 104. The gate stacking structure 120 and the channel structure CH may be disposed on the second substrate 110 in the cell array region 102. A structure that connects the gate stacking structure 120 and/or the channel structure CH in the cell array region 102 to the circuit region 200 or an external circuit may be in the cell array region 102 and/or the connection region 104.

In embodiments, the second substrate 110 may include a semiconductor layer including a semiconductor material. For example, the second substrate 110 may be a semiconductor substrate including or formed of a semiconductor material or may be a semiconductor substrate in which a semiconductor layer is disposed on a base substrate. For example, the second substrate 110 may include or be formed of silicon, germanium, silicon-germanium, silicon on insulator (SOI), germanium on insulator (GOI), or so on. A p-type dopant or an n-type dopant may be doped to the semiconductor layer included in the second substrate 110. For example, the p-type dopant may include as boron (B), gallium (Ga), or so on, and the n-type dopant may include phosphorus (P), arsenic (As), or so on. However, the embodiments are not limited to a material of the second substrate 110, a conductive type of the dopant doped to the semiconductor layer, or so on.

In the cell array region 102, the gate stacking structure 120 and the channel structure CH may be disposed. The gate stacking structure 120 may include cell insulation layers 132 and gate electrode layers 130 alternately stacked on a first surface (e.g., a front surface or an upper surface) of the second substrate 110. The channel structure CH may extend in a thickness direction of the semiconductor device 10 (a Z-axis direction in the drawings, for example, a vertical direction) while passing through or penetrating the gate stacking structure 120.

In embodiments, horizontal conductive layers 112 and 114 may be provided between the second substrate 110 and the gate stacking structure 120 in the cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 sequentially on the second substrate 110. The first horizontal conductive layer 112 may act as a partial portion of a common source line of the semiconductor device 10. For example, the first horizontal conductive layer 112 may act as the common source line together with the second substrate 110.

The first and second horizontal conductive layers 112 and 114 may include or be formed of a semiconductor material (e.g., polycrystalline silicon). For example, the first horizontal conductive layer 112 may include or be formed of a polycrystalline silicon layer including a dopant. The embodiments are not limited thereto. The second horizontal conductive layer 114 may include or be formed of a material (e.g., an insulating material) different from a material of the first horizontal conductive layer 112, or the second horizontal conductive layer 114 may not be provided.

The gate stacking structure 120 may be disposed on the second substrate 110 (e.g., on the first and second horizontal conductive layers 112 and 114 on the second substrate 110). The gate stacking structure 120 may include cell insulation layers 132 and gate electrode layers 130 alternately stacked to each other.

The gate electrode layer 130 may include any of various conductive materials. For example, the gate electrode layer 130 may include or be formed of a metal material (e.g., tungsten (W), copper (Cu), aluminum (Al), or so on), polycrystalline silicon, metal nitride (e.g., titanium nitride (TiN), tantalum nitride (TaN), or so on), or a combination thereof. As illustrated in an enlarged view of FIG. 2, a partial portion of a blocking layer 156 (e.g., a first blocking layer 156a) including or being formed of an insulating material may be disposed outside the gate electrode layer 130. The cell insulation layer 132 may include any of various insulating materials. For example, the cell insulation layer 132 may include silicon oxide, silicon nitride, silicon oxynitride, a low dielectric constant material having a lower dielectric constant than silicon oxide, or a combination thereof.

In embodiments, the channel structure CH may be provided. The channel structure CH may extend in the thickness direction of the semiconductor device 10 (the Z-axis direction in the drawings) to pass through the gate stacking structure 120.

The channel structure CH may include a channel layer 140, and a gate dielectric layer 150 on the channel layer 140 between the gate electrode layer 130 and the channel layer 140. The channel structure CH may further include a core insulation layer 142 at an inside of the channel layer 140. In some embodiments, the core insulation layer 142 may not be provided. The channel structure CH may further include a channel pad 144 on the channel layer 140 and/or the gate dielectric layer 150. The gate dielectric layer 150 between the gate electrode layer 130 and the channel layer 140 may include a tunneling layer 152, a charge storage layer 154, and a blocking layer 156 sequentially on the channel layer 140.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape, a zigzag shape, or so on in a plan view. The channel structure CH may have a pillar shape. For example, the channel structure CH may have an inclined side surface such that a width of the channel structure CH decreases toward the second substrate 110 due to an aspect ratio. However, the embodiments are not limited thereto, and an arrangement, a structure, a shape, or so on of the channel structure CH may be variously modified.

The channel layer 140 may include a semiconductor material (e.g., polycrystalline, epitaxial, or single-crystalline silicon). The core insulation layer 142 may include any of various insulating materials. For example, the core insulation layer 142 may include or be formed of silicon oxide, silicon nitride, silicon oxynitride, or a combination thereof.

The tunneling layer 152 may include or be formed of an insulating material that is capable of tunneling a charge (e.g., silicon oxide, silicon oxynitride, or so on). The charge storage layer 154 may be used as a data storage region, and the charge storage layer 154 may include or be formed of polycrystalline silicon, silicon nitride, or so on. The blocking layer 156 may include or be formed of an insulating material that is capable of preventing an undesirable flow of charge into the gate electrode layer 130. The blocking layer 156 may include or be formed of, for example, silicon oxide, silicon nitride, silicon oxynitride, a high dielectric constant material having a higher dielectric constant than silicon oxide, or a combination thereof. In embodiments, the blocking layer 156 may include a first blocking layer 156a including a portion horizontally extending on the gate electrode layer 130, and a second blocking layer 156b vertically extending between the first blocking layer 156a and the charge storage layer 154.

However, a material, a stacking structure, or so on of the channel layer 140, the core insulation layer 142, or the gate dielectric layer 150 may be variously modified, and the embodiments are not limited thereto.

The channel pad 144 may cover an upper surface of the core insulation layer 142 and be disposed to be electrically connected to the channel layer 140. The channel pad 144 may include or be formed of a conductive material (e.g., polycrystalline silicon doped with a dopant), but the embodiments are not limited thereto.

In embodiments, the gate stacking structure 120 may include a plurality of gate stacking portions 121 and 122 sequentially stacked. Thereby, a number of stacked gate electrode layers 130 may be increased, and a number of memory cells may be increased with a stable structure. In FIG. 1, it is illustrated as an example that the gate stacking structure 120 includes first and second gate stacking portions 121 and 122. In some embodiments, the gate stacking structure 120 may include one gate stacking portion or three or more gate stacking portions.

When the plurality of gate stacking portions 121 and 122 are provided as in the above, the channel structure CH may include a plurality of channel portions CH1 and CH2 that respectively pass through the plurality of gate stacking portions 121 and 122. The plurality of channel portions CH1 and CH2 may have a shape in which the plurality of channel portions CH1 and CH2 are connected to each other. In a cross-sectional view, each of the plurality of channel portions CH1 and CH2 may have an inclined side surface such that a width of each of the plurality of channel portions CH1 and CH2 decreases toward the second substrate 110 according to an aspect ratio. A bent portion due to a difference in widths of the plurality of channel portions CH1 and CH2 may be provided at a boundary portion of the plurality of channel portions CH1 and CH2. In some embodiments, the plurality of channel portions CH1 and CH2 may have an inclined side surface that is continuously extended without the bent portion. In FIG. 2, it is illustrated as an example that the gate dielectric layer 150, the channel layer 140, and the core insulation layer 142 of the plurality of channel portions CH1 and CH2 continuously extend to have an integral structure. In some embodiments, gate dielectric layers 150, channel layers 140, and core insulation layers 142 of the plurality of channel portions CH1 and CH2 may be separately formed and be electrically connected to each other. In some embodiments, a separate channel pad may be additionally disposed at the boundary portion of the plurality of channel portions CH1 and CH2. As such, the embodiments are not limited to a shape of a plurality of channel portions CH1 and CH2.

In embodiments, the gate stacking structure 120 may be divided into a plurality of portions in a plan view by a separation structure 146 extending in the thickness direction of the semiconductor device 10 (the Z-axis direction in the drawings) to pass through the gate stacking structure 120. An upper separation region 148 may be at a portion adjacent to an upper portion of the gate stacking structure 120. In a plan view, a plurality of separation structures 146 and/or a plurality of upper separation regions 148 may extend in an extension direction (an X-axis direction in the drawings) of the gate electrode layer 130 and be spaced apart from each other at a predetermined interval in a crossing direction or a transverse direction (a Y-axis direction in the drawings) that crosses or transverse to the gate electrode layer 130.

The separation structure 146 and/or the upper separation region 148 may be filled with any of various insulating materials. For example, the separation structure 146 or the upper separation region 148 may include an insulating material such as silicon oxide, silicon nitride, or silicon oxynitride. However, the embodiments are not limited thereto, and a structure, a shape, a material, or so on of the separation structure 146 or the upper separation region 148 may be variously modified.

The connection region 104 and the second wiring portion 180 may be provided to connect the gate stacking structure 120 and the channel structure CH in the cell array region 102 to the circuit region 200 or an external circuit. The connection region 104 may be at a periphery of the cell array region 102 and a partial portion of the second wiring portion 180 may be in the connection region 104.

The second wiring portion 180 may include a member electrically connecting the gate electrode layer 130, the channel structure CH, the horizontal conductive layers 112 and 114, and/or the second substrate 110 to the circuit region 200 or the external circuit. For example, the second wiring portion 180 may include a bit line 182, a gate contact portion 184, a source contact portion 186, a through plug 188, a contact via 180a, and a connection wiring 180b. The contact via 180a may be connected to each of the bit line 182, the gate contact portion 184, the source contact portion 186, and/or the through plug 188. The connection wiring 180b may be electrically connected to the bit line 182, the gate contact portion 184, the source contact portion 186, the through plug 188, and/or the contact via 180a.

The bit line 182 may extend in the crossing direction or the transverse direction (the Y-axis direction in the drawings) that crosses or is transverse to the extension direction (the X-axis direction in the drawings) of the gate electrode layer 130. The bit line 182 may be electrically connected to the channel structure CH (e.g., the channel pad 144) through the contact via 180a (e.g., a bit line contact via) that passes through or penetrates the cell insulation layer 132.

In the connection region 104, a plurality of gate contact portions 184 may pass through the cell insulation layer 132 to be electrically connected to the plurality of gate electrode layers 130, respectively, extended to the connection region 104. In the drawing, it is illustrated as an example that the plurality of gate electrode layers 130 have a stair shape in one direction or a plurality of directions in the connection region 104, but the embodiments are not limited thereto. In the connection region 104, the source contact portion 186 may pass through the cell insulation layer 132 to be electrically connected to the horizontal conductive layers 112 and 114 and/or the second substrate 110. The through plug 188 may pass through or penetrate the gate stacking structure 120 or may be disposed at an outside of the gate stacking structure 120 to be electrically connected to the first wiring portion 280 of the circuit region 200.

In FIG. 1, it is illustrated as an example that each of the gate contact portion 184, the source contact portion 186, and/or the through plug 188 has an inclined side surface such that a width of each of the gate contact portion 184, the source contact portion 186, and/or the through plug 188 decreases toward the second substrate 110 due to an aspect ratio and a bent portion is provided at the boundary portion of the plurality of gate stacking portions 121 and 122 in a cross-sectional view. However, the embodiments are not limited thereto. In some embodiments, the gate contact portion 184, the source contact portion 186, and/or the through plug 188 may not include the bent portion at the boundary portion of the plurality of gate stacking portions 121 and 122. Other various modified embodiments are possible.

In FIG. 1, it is illustrated as an example that the connection wiring 180b is a single layer on the same plane as the bit line 182 and a second insulation layer 134 is at a portion other than the second wiring portion 180. However, this is brief illustration for convenience. For an electrical connection with the bit line 182, the gate contact portion 184, the source contact portion 186, and/or the through plug 188, the connection wiring 180b may include a plurality of wiring layers and a contact via may be further included.

The second wiring portion 180 may be electrically connected to the first wiring portion 280, and the bit line 182 connected to the channel structure CH, the gate electrode layer 130, the horizontal conductive layers 112 and 114, and/or the second substrate 110 may be electrically connected to a circuit element 220 of the circuit region 200.

The circuit region 200 may include a first substrate 210, and a circuit element 220 and a first wiring portion 280 on the first substrate 210.

The first substrate 210 may be a semiconductor substrate including a semiconductor material. For example, the first substrate 210 may be a semiconductor substrate including or formed of a semiconductor material or may be a semiconductor substrate in which a semiconductor layer is disposed on a base substrate. For example, the first substrate 210 may include or be formed of silicon, germanium, or silicon-germanium, silicon on insulator, germanium on insulator, or so on.

The circuit element 220 on or at the first substrate 210 may include any of various circuit elements that control an operation of the memory cell structure in the cell region 100. For example, the circuit element 220 may constitute the peripheral circuit structure such as a decoder circuit 1110 (refer to FIG. 16), a page buffer 1120 (refer to FIG. 16), a logic circuit 1130 (refer to FIG. 16), or so on.

The circuit element 220 may include, for example, a plurality of transistors 300. In embodiments, the plurality of transistors 300 may include a first transistor 400 and a second transistor 500. This will be described later in more detail. The circuit element 220 may include not only an active element such as the transistor 300 or so on but also a passive element such as a capacitor, a resistor, an inductor, or so on.

The first wiring portion 280 on the first substrate 210 may be electrically connected to the circuit element 220. In embodiments, the first wiring portion 280 may include a plurality of wiring layers 286 that are spaced apart from each other while interposing a first insulation layer 282 therebetween and are electrically connected by a contact via 284 to form a desired path. The wiring layer 286 or the contact via 284 may include any of various conductive materials, and the first insulation layer 282 may include any of various insulating materials. For example, the first insulation layer 282 may include or be formed of at least one of silicon oxide, silicon nitride, and silicon oxynitride.

For example, among the plurality of wiring layers 286, a wiring layer 286 at an uppermost portion adjacent to the cell region 100 may include or constitute a pad portion to which the gate contact portion 184, the source contact portion 186, the through plug 188, or so on is connected.

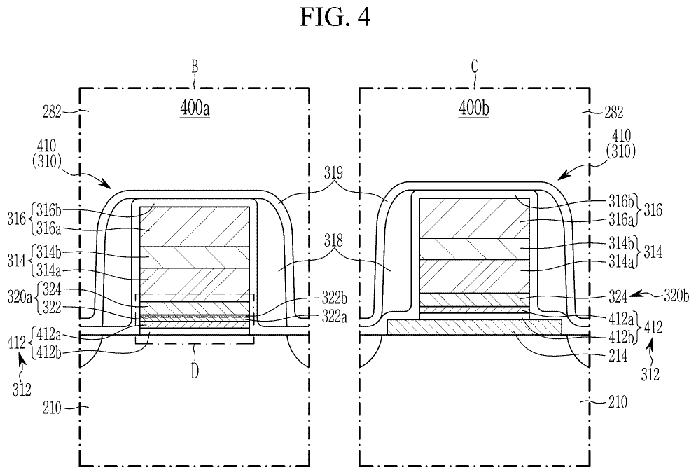

Referring to FIG. 3 and FIG. 4 together with FIG. 1 and FIG. 2, the plurality of transistors 300 included in the circuit region 200 will be described in detail.

FIG. 3 is an enlarged cross-sectional view of a portion A in FIG. 1. FIG. 4 is an enlarged cross-sectional view of a portion B and a portion C in FIG. 3. FIG. 3 illustrates a cross-sectional view of the transistor 300 where a gate structure 310 and source and drain regions 300s and 300d are disposed together.

Referring to FIG. 1 to FIG. 4, in embodiments, a plurality of transistors 300 may include a first transistor 400, and a second transistor 500 having an operating voltage greater than an operating voltage of the first transistor 400.

For example, the first transistor 400 may be a low voltage (LV) transistor having a relatively low operating voltage, and the second transistor 500 may be a high voltage (HV) transistor having a relatively high operating voltage. For example, the operating voltage of the first transistor 400 may be in a range from about 0.1V to about 10V, and the operating voltage of the second transistor 500 may greater than the operating voltage of the first transistor 400 and be in a range from about 10V to about 100V. The terms of the low voltage transistor and the high voltage transistor may be used to distinguish between each other, but the embodiments are not limited thereto. Further, the embodiments are not limited to ranges of the operating voltages of the first transistor 400 and/or the second transistor 500.

In embodiments, the first transistor 400, which is the low voltage transistor, may have a high-speed operation property and excellent reliability, and thus, may be applied to a transistor that requires high-speed operation. For example, at least a part of transistors included in a decoder circuit 1100 (refer to FIG. 16), a page buffer 1120 (refer to FIG. 16), a logic circuit 1130 (refer to FIG. 16) may be the first transistor 400.

For example, the first transistor 400 may include a first conductivity type transistor 400a and a second conductivity type transistor 400b. In the first conductivity type transistor 400a, source and drain regions 300s and 300d may have a first conductivity type, and an active region may be formed of a second conductivity type well that has a second conductivity type opposite to the first conductivity type. In the second conductivity type transistor 400b, source and drain regions 300s and 300d may have the second conductivity type, and an active region may be formed of a first conductivity type well that has the first conductivity type. For example, the first conductivity type may be an n-type and the second conductivity type may be a p-type. Thereby, the first conductivity type transistor 400a may be an n-type metal oxide semiconductor (NMOS) transistor, and the second conductivity type transistor 400b may be a p-type metal oxide semiconductor (PMOS) transistor. However, the embodiments are not limited thereto.

In embodiments, the first transistor 400 may include a high dielectric constant insulation layer (a high-k dielectric layer) 412a and a second electrode layer 314b to have a high dielectric constant metal gate (high-k metal gate, HKMG) structure. The high dielectric constant insulation layer 412a may include or be formed of a high dielectric constant material, and the second electrode layer 314b may include or be formed of a metal layer. By the high dielectric constant insulation layer 412a, a thickness of the high dielectric constant insulation layer 412a may be reduced and an excellent electrical insulation property may be maintained. By the second electrode layer 314b, performance of the first transistor 400 may be improved and a size of the first transistor 400 may be reduced.

Since the first transistor 400 of the low voltage transistor capable of performing the high speed operation may have the high dielectric constant metal gate structure, speed may be effectively improved. Thereby, performance of the first transistor 400 may be improved. When the first transistor 400 may have the high dielectric constant metal gate structure, which is different from a structure of the second transistor 500, as in the above, a large number of transistors 300 having different structures or heights may be included.

The second transistor 500, which is the high voltage transistor, may be applied to a transistor that generates or transmits a high voltage. For example, at least a part of transistors included in the decoder circuit 1110 (refer to FIG. 16), the page buffer 1120 (refer to FIG. 16), or so on may be the second transistor 500. For example, the second transistor 500 may be a pass transistor that applies a voltage to the gate electrode layer 130 included in the gate stacking structure 120.

For a clear understanding and simple illustration, in the drawings, it is illustrated as an example that the first transistor 400 is disposed at a lower portion of the cell array region 102, and the second transistor 500 is disposed at a lower portion of the connection region 104. However, the embodiments are not limited thereto. For example, at least one of the first transistor 400 and the second transistor 500 may be disposed at the lower portion of the cell array region 102, or at least one of the first transistor 400 and the second transistor 500 may be disposed at the lower portion of the connection region 104. Positions of the first transistor 400 and the second transistor 500 may be variously modified.

In embodiments, each of the plurality of transistors 300 may include a gate insulation layer 312 and a gate electrode 314 sequentially disposed at least on the first substrate 210, and may further include a capping layer 316, a spacer 318, and a cover layer 319. Portions of the capping layer 316, the spacer 318, and the cover layer 319 on the gate electrode 314 may be regarded as a portion of a gate structure 310. The plurality of transistors 300 may have differences whether an intermediate layer (e.g., a first intermediate layer 320a or a second intermediate layer 320b) is included or not and/or whether a semiconductor layer 214 is included or not.

In embodiments, the plurality of transistors 300 may have different stacking structures. For example, the first conductivity type transistor 400a may include a gate insulation layer 312, an intermediate layer (e.g., a first intermediate layer 320a), and a gate electrode 314 sequentially disposed on the first substrate 210. For example, the second conductivity type transistor 400b may include a semiconductor layer 214, a gate insulation layer 312, an intermediate layer (e.g., a second intermediate layer 320b), and a gate electrode 314 sequentially disposed on the first substrate 210. For example, the second transistor 500 may include a gate insulation layer 312 and a gate electrode 314 sequentially disposed on the first substrate 210. That is, the first conductivity type transistor 400a may not include the semiconductor layer 214, and the second transistor 500 may not include the semiconductor layer 214, and a layer corresponding to the intermediate layer (e.g., the first intermediate layer 320a or the second intermediate layer 320b).

Hereinafter, the first substrate 210, the gate insulation layer 312, the gate electrode 314, the capping layer 316, the spacer 318, and the cover layer 319 that are related to or included in the plurality of transistors 300 will be described. After that, the gate insulation layer 312 (e.g., a first gate insulation layer 412) of the first transistor 400 and the gate insulation layer 312 (e.g., a second gate insulation layer 512) of the second transistor 500 will be described. After that, the first conductivity type transistor 400a, the second conductivity type transistor 400b, and the second transistor 500 will be described in detail.

In embodiments, the first substrate 210 may have a first surface 2101 and a second surface 2102 opposite to each other. A device isolator 212 may be disposed in a portion adjacent to the first surface 2101 of the first substrate 210. The device isolator 212 may be at a boundary or boundaries of the plurality of transistors 300 to separate, divide, or define active regions of the plurality of transistors 300 at the portion adjacent to the first surface 2101 of the first substrate 210. The active region may have a first conductivity type well or a second conductivity type well according to a conductivity type of a channel portion that is included in each transistor 300.

For example, the device isolator 212 may be an insulator having a shallow trench isolation (STI) structure for separating, dividing, or define the active regions of the transistors 300. The device isolator 212 may penetrate or pass through a partial portion of the first substrate 210. In the drawings, it is illustrated as an example that a first surface of the device isolator 212 adjacent to the first surface 2101 of the first substrate 210 is disposed on the same plane as the first surface 2101 of the first substrate 210, but the embodiments are not limited thereto. Depending on an process order of the device isolator 212, the first surface of the device isolator 212 may be disposed on a plane different from the first surface 2101 of the first substrate 210. For example, the first surface of the device isolator 212 may be disposed higher than the first surface 2101 of the first substrate 210.

For example, the device isolator 212 may include or be formed of at least one of silicon oxide, silicon nitride, silicon oxynitride, and a low dielectric constant material. However, the embodiments are not limited thereto. The device isolator 212 may include or be formed of any of various materials.

In embodiments, each transistor 300 may have a planar structure. That is, the gate insulation layer 312 and the gate electrode 314 may horizontally extend, and source and drain regions 300s and 300d may be disposed at opposite sides of the gate insulation layer 312 and the gate electrode 314 in a plan view. For example, the source and drain regions 300s and 300d may be disposed at portions of the first substrate 210 at opposite sides of the gate insulation layer 312 and the gate electrode 314 in a plan view. The transistor 300 having the planar structure may be stably applied to a memory device (e.g., a flash memory device) including the plurality of transistors 300 having various operating voltages or performing various acts. However, the embodiments are not limited thereto, and at least one of the plurality of transistors 300 may have a structure different from a planar structure.

In embodiments, the gate insulation layer 312 may have a layered shape that horizontally extends on the first surface 2101 of the first substrate 210, and the gate electrode 314 may have a layered shape that horizontally extends on the gate insulation layer 312.

The gate insulation layer 312 may be disposed between the first substrate 210 and the gate electrode 314, or between the semiconductor layer 214 and the gate electrode 314 on the first substrate 210. The gate insulation layer 312 may include an insulating material. The gate insulation layer 312 may include a single layer of a plurality of layers.

The gate electrode 314 may include or be formed of a conductive material and may have a relatively large thickness. The gate electrode 314 may include a single layer of a plurality of layers.

In embodiments, the gate electrode 314 may include or be formed of a semiconductor material and/or a metallic material. For example, the gate electrode 314 may include or be formed of at least one or metal, a metal alloy, metal silicide, and a doped semiconductor material. The metal or the metal alloy included in the gate electrode 314 may include or be formed of at least one of Ti, W, Mo, Al, Cu, Ni, Mg, Co, Ta, Ru, Au, and Sr. The doped semiconductor material may include or be formed of a semiconductor material (e.g., a polycrystalline semiconductor material) doped with an n-type dopant or a p-type dopant. The gate electrode 314 may further include metal oxide or metal oxynitride in which the above material is oxidized or nitrided.

In embodiments, the gate electrode 314 may include a semiconductor layer and/or a metal-including layer (e.g., a metal layer including or formed of metal or a metal alloy). In the drawings, it is illustrated as an example that the gate electrode 314 includes a first electrode layer 314a including a semiconductor layer and a second electrode layer 314b including a metal layer. However, the embodiments are not limited thereto, and a material, a stacking structure, or the like of the gate electrode 314 may be variously modified. In some embodiments, the gate electrode 314 may further include a barrier layer of a metal layer and/or a metal nitride layer between the first electrode layer 314a and the second electrode layer 314b.

The capping layer 316 may be disposed on the gate electrode 314. The capping layer 316 may include a first capping layer 316a on an upper surface of the gate electrode 314, and may further include a second capping layer 316b at least on a side surface of the gate electrode 314.

For example, the first capping layer 316a may have a layered shape that horizontally extends on the gate electrode 314. The second capping layer 316b may be disposed on an upper surface and/or a side surface of the first substrate 210, the semiconductor layer 214, the gate insulation layer 312, the first and second intermediate layers 320a and 320b, the gate electrode 314, and the first capping layer 316a.

The first capping layer 316a may act as a mask layer in a patterning process of the gate insulation layer 312 and the gate electrode 314. The first capping layer 316a may be referred to as a mask layer. The first capping layer 316a may protect the gate electrode 314 on the upper surface of the gate electrode 314. For example, the first capping layer 316a may prevent an unwanted material or element (e.g., hydrogen) from penetrating into the gate electrode 314 or so on.

As in the above, the first capping layer 316a may be used as the mask layer, and the gate insulation layer 312, the gate electrode 314, and the first capping layer 316a may have the same or similar planar shape. The same or similar planar shape may refer to a case having the same planar shape and a case having a planar shape with a difference within a process error.

The second capping layer 316b may prevent an unwanted material or element (e.g., hydrogen) from penetrating into the first substrate 210, the semiconductor layer 214, the gate insulation layer 312, the first and second intermediate layers 320a and 320b, and the gate electrode 314.

The first capping layer 316a or the second capping layer 316b may include any of various insulating materials. In embodiments, the first capping layer 316a or the second capping layer 316b may include a material different from a material of the spacer 318. The first capping layer 316a or the second capping layer 316b may include or be formed of any of various insulating materials such as nitride, oxynitride, or so on. For example, the first capping layer 316a or the second capping layer 316b may include or be formed of at least one of silicon nitride and silicon oxynitride. However, the embodiments are not limited thereto. A material of the first capping layer 316a or the second capping layer 316b may be variously modified.

The spacer 318 may be disposed at least on the side surface of the gate electrode 314. For example, the spacer 318 may be disposed on the second capping layer 316b that is disposed on the upper surface of the first substrate 210, the upper surface and/or the side surface of the semiconductor layer 214, and side surfaces of the gate insulation layer 312, the first or second intermediate layers 320a or 320b, the gate electrode 314, and the first capping layer 316a.

The spacer 318 may electrically insulate the gate electrode 314 and the source and drain regions 300s and 300d. For example, in a plan view, the spacers 318 may be disposed at least at opposite sides of the gate electrode 314, respectively, in a crossing direction or a transverse direction that crosses or is transverse to an extension direction of the gate electrode 314. In a plan view, the spaces 318 may be disposed between the gate electrode 314 and the source and drain regions 300s and 300d. In a plan view, the spacer 318 may extend in the extension direction of the gate electrode 314.

The spacer 318 may include any of various insulating materials such as oxide, nitride, oxynitride, a low dielectric constant material, or so on. For example, the spacer 318 may include or be formed of a material that includes at least one of silicon oxide, silicon nitride, and silicon oxynitride, or may include or be formed of a material in which carbon is additionally included in the above material. The spacer 318 may include a single layer of a plurality of layers. However, the embodiments are not limited thereto. The spacer 318 may include any of various materials other than the above material.

The source and drain regions 300s and 300d may be formed of doping regions formed by doping a dopant to partial portions of the first substrate 210. For example, the source or drain region 300s or 300d may be a portion formed by doping an n-type dopant or a p-type dopant to a partial portion of the first substrate 210. A dopant of the source and drain regions 300s and 300d may have a conductivity type opposite to a conductive type of the active region (e.g., the first conductivity type well or the second conductivity type well) of the transistor 300. However, the embodiments are not limited thereto. The source and drain regions 300s and 300d may include any of various materials or have any of various structures or so on.

The cover layer 319 may be disposed at least on the capping layer 316 and the spacer 318. The cover layer 319 may be a kind of a capping layer that prevents an unwanted material or element (e.g., hydrogen) from penetrating into the first substrate 210, the semiconductor layer 214, the gate insulation layer 312, the first and second intermediate layers 320a and 320b, the gate electrode 314, and the source and drain regions 300s and 300d.

The cover layer 319 may include any of various insulating materials. In embodiments, the cover layer 319 may include a material different from a material of the spacer 318. The cover layer 319 may include or be formed of any of various insulating materials such as nitride, oxynitride, or so on. For example, the cover layer 319 may include or be formed of at least one of silicon nitride and silicon oxynitride. When the cover layer 319 includes silicon nitride, the cover layer 319 may effectively prevent hydrogen included in the first insulation layer 282 from moving. However, the embodiments are not limited thereto.

The first insulation layer 282 may be disposed to cover the plurality of transistors 300. A plurality of contact vias 284 may penetrate or pass through the first insulation layer 282 and be electrically connected to the plurality of transistors 300, respectively. For a clear understanding and simple illustration, in the drawings, the plurality of contact vias 284 electrically connected to the source and drain regions 300s and 300d are illustrated. The plurality of contact vias 284 may be electrically connected to the source and drain regions 300s and 300d, and the gate electrode 314, respectively. The contact via 284 electrically connected to the gate electrode 314 may penetrate or pass through the first insulation layer 282, the cover layer 319, and the capping layer 316 to be connected to the gate electrode 314.

In embodiments, the gate insulation layer 312 (i.e., a first gate insulation layer 412) that is included in the first transistor 400 and the gate insulation layer 312 (i.e., a second gate insulation layer 512) that is included in the second transistor 500 may include or have different materials, stacking structures, or thicknesses.

The phrase that the first gate insulation layer 412 and the second gate insulation layer 512 include different materials or have different stacking structures may refer to a case that a number of a layer or layers included in the first gate insulation layer 412 is different from a number of a layer or layers included in the second gate insulation layer 512, a layer including a material that is not included in the first gate insulation layer 412 is included in the second gate insulation layer 512, a layer including a material that is not included in the second gate insulation layer 512 is included in the first gate insulation layer 412, at least one layer of a plurality of layers that are included in the first gate insulation layer 412 is not included in the second gate insulation layer 512, or at least one layer of a plurality of layers that are included in the second gate insulation layer 512 is not included in the first gate insulation layer 412.

The first gate insulation layer 412 included in the first transistor 400 may include a single layer of a plurality of layers.

The first gate insulation layer 412 may include or be formed of a high dielectric constant insulation layer 412a. The high dielectric constant insulation layer 412a may have a dielectric constant greater than a dielectric constant of a material (e.g., silicon oxide) that is included in at least a partial portion of the second gate insulation layer 512 in the second transistor 500. The first gate insulation layer 412 may further include an interfacial layer 412b.

The high dielectric constant insulation layer 412a may include or be formed of at least one of hafnium oxide (HfO), hafnium silicon oxide (HfSiO), hafnium oxynitride (HfON), hafnium silicon oxynitride(HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO).

The interfacial layer 412b may be disposed between the first substrate 210 and the high dielectric constant insulation layer 412a or between the semiconductor layer 214 and the high dielectric constant insulation layer 412a, thereby improving an interface property of the first gate insulation layer 412. For example, in the first conductivity type transistor 400a, the interfacial layer 412b may be disposed between the first substrate 210 and the high dielectric constant insulation layer 412a and be in contact with each of the first substrate 210 and the high dielectric constant insulation layer 412a. In the second conductivity type transistor 400b, the interfacial layer 412b may be disposed between the semiconductor layer 214 and the high dielectric constant insulation layer 412a and be in contact with each of the semiconductor layer 214 and the high dielectric constant insulation layer 412a. However, the embodiments are not limited thereto, and the interfacial layer 412b may be omitted.

The interfacial layer 412b may have a dielectric constant less than a dielectric constant of the high dielectric constant insulation layer 412a. For example, the interfacial layer 412b may include or be formed of at least one of oxide (e.g., silicon oxide) and oxynitride (e.g., silicon oxynitride).

The second gate insulation layer 512 included in the second transistor 500 may include a material different from a material of the first gate insulation layer 412 included in the first transistor 400, or have a stacking structure or a thickness different from a stacking structure or a thickness of the first gate insulation layer 412 included in the first transistor 400.

The second gate insulation layer 512 may include or be formed of at least one of oxide, nitride, oxynitride, and a low dielectric constant material having a lower dielectric constant than silicon oxide. For example, the second gate insulation layer 512 may include or be formed of at least one of silicon oxide, silicon nitride, and silicon oxynitride. The second gate insulation layer 512 may include a single layer of a plurality of layers.

A thickness of the second gate insulation layer 512 may be greater than a thickness of the first gate insulation layer 412. A channel length (a distance between the source region 300s and the drain region 300d) in the second transistor 500 may be greater than a channel length (a distance between the source region 300s and the drain region 300d) in the first transistor 400. In the crossing direction or the transverse direction that crosses or is transverse to the extension direction of the gate electrode 314, a width of the gate electrode 314 of the second transistor 500 may be greater than a width of the gate electrode 314 of the first transistor 400. Thereby, the second transistor 500, which is the high voltage transistor, may stably withstand a high potential difference between the gate electrode 314 and the source and drain regions 300s and 300d.

The first conductivity type transistor 400a may include a gate structure 310 (e.g., a first gate structure 410) and source and drain regions 300s and 300d. In the first conductivity type transistor 400a, the first gate structure 410 may include the first gate insulation layer 412, the first intermediate layer 320a, the gate electrode 314, the capping layer 316, the spacer 318, and the cover layer 319 disposed on the first substrate 210. For example, in the first conductivity type transistor 400a, the first gate insulation layer 412 may be in contact with the first substrate 210 and the gate electrode 314, respectively.

In the first conductivity type transistor 400a, the first intermediate layer 320a disposed between the first gate insulation layer 412 and the gate electrode 314 may control or adjust a work function and control (e.g. reduce) a threshold voltage of the first conductivity type transistor 400a. At least a portion of the first intermediate layer 320a may act as a kind of a gate insulation layer together with the first gate insulation layer 412, and/or may act as a kind of a gate electrode together with the gate electrode 314. For example, the first intermediate layer 320a may be referred to as a buffer layer, a buffer electrode layer, a work function control layer, a work function layer, an insertion layer, or so on.

In embodiments, the first intermediate layer 320a may include a first layer 322 on the first gate insulation layer 412, and may further include a second layer 324 that is disposed on the first layer 322 and has a work function different from a work function of the first layer 322 (e.g., a first region 322a). For example, the work function of the second layer 324 may be greater than the work function of the first layer 322.

For example, in the first conductivity type transistor 400a, the first layer 322 may be in contact with the first gate insulation layer 412. However, the embodiments are not limited thereto, and an additional layer may be disposed between the first gate insulation layer 412 and the first layer 322. For example, in the first conductivity type transistor 400a, the second layer 324 may be in contact with the first layer 322, and a structure and a process may be simplified. However, the embodiments are not limited thereto, and an additional layer may be disposed between the first layer 322 and the second layer 324. For example, in the first conductivity type transistor 400a, the gate electrode 314 may be in contact with the second layer 324, and a structure and a process may be simplified. However, the embodiments are not limited thereto, and an additional layer may be disposed between the second layer 324 and the gate electrode 314.

The first layer 322 (e.g., the first region 322a) may have a relatively low work function, and may be referred to as an n-type layer, an n-type function layer, or an n-type work function layer. The second layer 324 may have a work function greater than a work function of the first layer 322, and may be referred to as a p-type layer, a p-type function layer, or a p-type work function layer.

For example, the first layer 322 may include a material different from a material of the high dielectric constant insulation layer 412a or may have a composition different from a composition of the high dielectric constant insulation layer 412a. In some embodiments, when the first layer 322 includes a material same as a material of the high dielectric constant insulation layer 412a or may have a composition same as a composition of the high dielectric constant insulation layer 412a, the first layer 322 and the high dielectric constant insulation layer 412a may be separately seen, identified, or distinguished by a time difference of a manufacturing process.

In embodiments, the first layer 322 may include a first region 322a and a second region 322b. The first region 322a may be disposed on (e.g., in contact with) the first gate insulation layer 412 and may include first metal. The second region 322b may be disposed on the first region 322a to be spaced apart from the first gate insulation layer 412. The second region 322b may include the first metal and second metal different from the first metal.

For example, a preliminary layer of the first region 322a including the first metal may be formed, and thereafter, the second metal may be partially doped to a portion (e.g., an upper portion) of the preliminary layer to form the second region 322b. That is, the first region 322a of the first layer 322 may be an undoped region to which the second metal is not doped and a region other than an ion implantation region to which the second metal is doped. The second region 322b of the first layer 322 may be a doped region or an ion implantation region to which the second metal is doped.

For a clear understanding, it is described as an example that the first region 322a and the second region 322b are included in the first layer 322, but the first region 322a and the second region 322b may be regarded as different layers including different materials or having different compositions. When the first region 322a and the second region 322b may be regarded as different layers including different materials or having different compositions, the first intermediate layer 320a may be regarded as having a three-layered structure including the first region 322a, the second region 322b, and the second layer 324.

The first region 322a may include or be formed of a layer including the first metal and oxygen. For example, the first region 322a may include or be formed of an oxide layer or an oxynitride layer including the first metal and the oxygen. The first region 322a may include any of various materials having a relatively small work function and being capable of reducing a threshold voltage of the first conductivity type transistor 400a, which is the NMOS transistor. For example, the first metal may include or be formed of lanthanum (La), and the first region 322 may include or be formed of lanthanum oxide or lanthanum oxynitride.

The second region 322b may include or be formed of a layer including the first metal, the second metal, and oxygen (e.g., a layer including the first metal and the oxygen and doped with the second metal). For example, the second region 322b may include or be formed of an oxide layer or an oxynitride layer including the first metal, the second metal, and the oxygen. That is, the second region 322b may include or be formed of a material in which the second metal is additionally doped in the first region 322a. The second metal may be additionally included in the second region 322b by a doping process (e.g., an ion implantation process). For example, the second metal may be disposed at an interstitial site in the second region 322b. However, the embodiments are not limited thereto, and the second metal may be disposed at a position in the second region 322b other than the interstitial site by a diffusion in a subsequent heat treatment or so on.

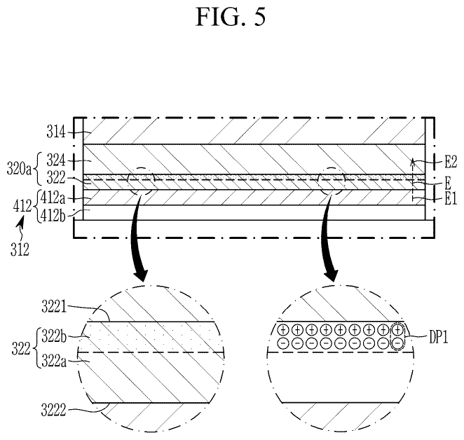

The second metal may have an oxygen areal density different from an oxygen areal density of the first metal. Thereby, the second metal may induce a movement of the oxygen included in the first layer 322 and a partial dipole may be formed in a portion (e.g., an upper portion) of the first layer 322. The partial dipole may be formed in a portion of the first layer 322 in the thickness direction of the semiconductor device 10 (the Z-axis direction in the drawings), for example, a portion adjacent to a first surface 3221 (refer to FIG. 5) (an upper surface in the drawings) of the first layer 322 that is adjacent to the second layer 324 or the gate electrode 314. The second region 322b may be regarded as a dipole induction layer or a dipole generation layer.

An oxygen-amount change region in which an amount of the oxygen is changed may be disposed in a portion of the first layer 322 by an oxygen movement. The oxygen-amount change region may be adjacent to the first surface 3221 of the first layer 322, and may be spaced apart from a second surface 3222 (refer to FIG. 5) (a lower surface in the drawings) of the first layer 322 or the first gate insulation layer 412. The second surface 3222 of the first layer 322 may be opposite to the first surface 3221 of the first layer 322 or may be adjacent to the first gate insulation layer 412. In a portion of the first layer 322 adjacent to the second surface 3222 of the first layer 322 in the thickness direction (the Z-axis direction in the drawings), an isolation region may be disposed to isolate or separate the oxygen-amount change region from the second surface 3222 of the first layer 322. The oxygen-amount change region may be disposed in a portion corresponding to at least a portion of the second region 322b, and the isolation region may be disposed in a portion corresponding to at least a portion of the first region 322a. This will be described in detail with reference to FIG. 5 to FIG. 9.

When the partial dipole is formed in the portion adjacent to the first surface 3221 of the first layer 322, an effective work function in the portion adjacent to the first surface 3221 of the first layer 322 may change and a threshold voltage of the first conductivity type transistor 400a, which is the NMOS transistor, may be controlled (e.g. reduced). Thereby, the first conductivity type transistor 400a may be driven at low power.

The second metal may include or be formed of at least one of a group 2 element, a transition metal, a group 13 element, a group 14 element, and a group 15 element. For example, the second metal may include or be formed of at least one of strontium (Sr), yttrium (Y), titanium (Ti), zirconium (Zr), hafnium (Hf), vanadium (V), niobium (Nb), tantalum (Ta), dubnium (Db), aluminum (Al), germanium (Ge), tin (Sn), and arsenic (As).

For example, the second metal may include or be formed of at least one of strontium, yttrium, titanium, zirconium, hafnium, niobium, and germanium. Thereby, the second region 322b may have a high dielectric constant and may constitute a portion of a high dielectric constant layer. For example, the second region 322b may have a dielectric constant greater than a dielectric constant of the first region 322a. However, the embodiments are not limited thereto, and the second region 322b may have a dielectric constant same as or less than a dielectric constant of the first region 322a. When the second region 322b may constitute the high dielectric constant layer as in the above, capacitance may be increase by a high dielectric constant and speed of the first conductivity type transistor 400a may be further increased.

However, the embodiments are not limited thereto, and the second metal may include any of various materials that are capable of being doped to a portion of the first layer 322 by a doping process (e.g., an ion implantation process) and have the oxygen areal density different from the oxygen areal density of the first metal to induce the oxygen movement. In the description, it is described as an example that a dipole is formed in a portion adjacent to the first surface 3221 of the first layer 322 by using the second metal as a dopant to induce the oxygen movement. In some embodiments, a material different from metal may be used as a dopant. In some embodiments, a dipole may be formed in a portion adjacent to the first surface 3221 of the first layer 322 by using a method different from a method using the oxygen movement. In this instance, the first layer 322 may include or be formed of a material different from oxide or oxynitride.

As an amount of the second metal increases in the second region 322b, the threshold voltage of the first conductivity type transistor 400a may be reduced. As a thickness of the first layer 322 increases, the threshold voltage of the first conductivity type transistor 400a may be reduced. However, when the first layer 322 has a certain thickness or more, the first conductivity type transistor 400a may have a uniform threshold voltage. That is, there may be a limit to reducing the threshold voltage of the first conductivity type transistor 400a by increasing the thickness of the first layer 322. In embodiments, by the second region 322b in a portion of the first layer 322, the threshold voltage of the first conductivity type transistor 400a may be further reduced. That is, the limitation of the threshold voltage reduction by an increase in the thickness of the first layer 322 may be overcome by the second region 322b.

In embodiments, the second layer 324 may include any of various materials having a work function greater than a work function of the first layer 322. For example, the second layer 324 may include titanium, tungsten, tantalum, aluminum, ruthenium, platinum, titanium nitride, tungsten nitride, tantalum nitride, titanium carbide, or tantalum carbide. The second layer 324 may further include metal oxide or metal oxynitride in which the above material is oxidized. The second layer 324 may be electrically conductive, and may act as a kind of a gate electrode.

The first intermediate layer 320a may be disposed between the first gate insulation layer 412 and the gate electrode 314, and may have a thickness less than a thickness of the first gate insulation layer 412 (e.g., the high dielectric constant insulation layer 412a) or the gate electrode 314. A thickness of the first layer 322 may be less than a thickness of the second layer 324, and may be less than a thickness of the semiconductor layer 214. As described in the above, when the first layer 322 has a certain thickness or more, the first conductivity type transistor 400a may have a uniform threshold voltage. Accordingly, the first layer 322 may have a relatively small thickness being capable of reducing the threshold voltage of the first conductivity type transistor 400a.

A thickness of the first region 322a may be greater than a thickness of the second region 322b. That is, in the first layer 322, a thickness of the first region 322a of a undoped region may be greater than a thickness of the second region 322b of a doped region. Thereby, a distance between the second region 322b of the doping region and the first gate insulation layer 412 may be sufficient, and an influence of the second region 322b, which is the doping region, on the first gate insulation layer 412 may be minimized. For example, a ratio of the thickness of the second region 322b to the thickness of the first layer 322 may be 0.3 or less (e.g., 0.1 or less). For example, the thickness of the second region 322 b may be 0.1nm or more. When the thickness of the second region 322 b may be 0.1nm or more, the partial dipole may be stably formed by the second region 322b. However, the embodiments are not limited thereto, and the ratio of the thickness of the second region 322b to the thickness of the first layer 322 may be greater than 0.3, or the thickness of the second region 322 b may be less than 0.1 nm.

In embodiments, the second region 322b may further include the second metal, and a ratio of the first metal in the second region 322b may be less than a ratio of the first metal in the first region 322a.

In embodiments, a doping depth may be controlled so that the first region 322a is not doped with the second metal in the doping process of the second metal. Accordingly, the second region 322b of the doping region may be separated from or spaced apart from the first region 322a and the first gate insulation layer 412 below the first region 322a, and the first region 322a and the first gate insulation layer 412 below the first region 322a may not substantially include the second metal. For example, an amount of the second metal in the second region 322b may be in a range of 10¹² atoms/cm³ or more, for example, in a range of 10¹² atoms/cm 3 to 10¹⁸atoms/cm3. For example, an amount of the second metal in the first region 322a or the first gate insulation layer 412 may be in a range of 10⁵ atoms/cm³ or less, for example, in a range of 1 atoms/cm³ or less. Accordingly, in the doping process of the second metal, damage, a property deterioration, or so on of the first gate insulation layer 412 may be minimized.

On the other hand, in a comparative example in which second metal is included in a first gate insulation layer, a property of the first gate insulation layer may be undesirably changed by the second metal. Further, if a doping process of the second metal may be performed by an ion implantation process to the extent that the second metal reaches the first gate insulation layer, the first gate insulation layer may be impacted or damaged by the ion implantation process.

In embodiments, the second layer 324 may not be disposed on the first layer 322 in the doping process of the second metal, and the doping process of the second metal may be performed in a state that the first layer 322 is exposed to an outside. The second metal may be disposed in a shallow region that is a portion of the first layer 322 in a thickness direction of the first layer 322. Accordingly, the doping process of the second metal may be easily performed, and an undesirable property deterioration of the second layer 324 may be prevented or reduced.

The second metal may be different from metal included in the second layer 324, or an amount of the second metal in the second region 322b may be different from an amount of the second metal in the second layer 324.

For example, when the second metal may be different from metal included in the second layer 324, the amount of the second metal may be highest in the second region 322b. That is, a portion having the highest amount of the second metal may be disposed within the first layer 322 or the second region 322b. For example, the portion having the highest amount of the second metal may be adjacent to the first surface 3221 of the first layer 322, and the amount of the second metal may be gradually reduced as it goes away from the first surface 3221 of the first layer 322 in the thickness direction of the first layer 322. The second layer 324 may not substantially include the second metal. Since the second layer 324 may be formed after forming the second region 322b using the doping process (e.g., ion implantation process) of the second metal, the second layer 324 may not substantially include the second metal. For example, the amount of the second metal in the second layer 324 may be in a range of 105 atoms/cm³ or less, for example, in a range of 1 atoms/cm³ or less. When the second metal is doped to the second region 322b by the ion implantation process, the second metal may not diffuse well to the second layer 324. Accordingly, even if a subsequent heat treatment process is performed, the second layer 324 may not substantially include the second metal. For example, in a surface (an upper surface in the drawings) of the second layer 324 opposite to the first layer 322, the second metal may not be substantially included. However, the embodiments are not limited thereto.

In some embodiments, when the second layer 324 includes the second metal, the amount of the second metal in the second region 322b may be different from the amount of the second metal in the second layer 324. This may be because the second metal may be included in the second region 322b by the doping process (e.g., the ion implantation process) of the second metal, and the second metal may be included in the second layer 324 by a process (e.g., a deposition process) for forming the second layer 324. For example, the portion having the highest amount of the second metal may be adjacent to the first surface 3221 of the first layer 322, and the amount of the second metal may be gradually reduced as it goes away from the first surface 3221 of the first layer 322 in the thickness direction of the first layer 322. The amount of the second metal in the second layer 324 may be substantially uniform in a thickness direction of the second layer 324, and may be different from the amount of the second metal in the first surface 3221 of the first layer 322. For example, the amount of the second metal may be discontinuous at an interface or a boundary (e.g., the first surface 3221 of the first layer 322) between the first layer 322 and the second layer 324. For example, the amount of the second metal in the first surface 3221 of the first layer 322 may be greater or less than the amount of the second metal inside the second layer 324. However, the embodiments are not limited thereto.

On the other than, if a dopant is doped by an ion implantation process after an additional layer (e.g. a layer including metal) is formed on a first layer, ions may be deflected by the additional layer or may not sufficiently penetrate the additional layer. Accordingly, the ion implantation process may not be performed to a desired degree, or a chamber performing the ion implantation process may be contaminated and mass production may be difficult. A dopant may be deeply or widely disposed in a thickness direction of the first layer such that the dopant penetrates the additional layer and reaches the first layer. That is, the dopant may be disposed in the additional layer on the first layer, and may reaches a gate insulation layer (e.g., a high dielectric constant insulation layer) below the first layer. When the dopant is disposed in the additional layer on the first layer, a property (e.g., electrical resistance) of the additional layer may be chanced or the additional layer may be impacted in the ion implantation process. When the dopant reaches the gate insulation layer (e.g., the high dielectric constant insulation layer), the gate insulation layer (e.g., the high dielectric constant insulation layer) may be impacted in the ion implantation process and a property of the gate insulation layer (e.g., the high dielectric constant insulation layer) may be deteriorated. The property of the gate insulation layer (e.g., the high dielectric constant insulation layer) may be directly related to performance of a transistor, and the performance of the transistor may be deteriorated. When a dipole is adjacent to a substrate, the dopant may induce scattering or so on in a channel portion and mobility in the channel portion may be deteriorated. Thereby, the performance of the transistor may be further deteriorated.

The second conductivity type transistor 400b may include a gate structure 310 (e.g., a first gate structure 410), and source and drain regions 300s and 300d. In the second conductivity type transistor 400b, the first gate structure 410 may include the semiconductor layer 214, the first gate insulation layer 412, the second intermediate layer 320b, the gate electrode 314, the capping layer 316, the spacer 318, and the cover layer 319 on the first substrate 210. For example, in the second conductivity type transistor 400b, the first gate insulation layer 412 may be in contact with the semiconductor layer 214 and the gate electrode 314, respectively.

In the second conductivity type transistor 400b, the semiconductor layer 214 may be disposed between the first substrate 210 and the first gate insulation layer 412. The semiconductor layer 214 may be in contact with the first substrate 210 and/or the first gate insulation layer 412, but the embodiments are not limited thereto. The second conductivity type transistor 400b may be different from the first conductivity type transistor 400a and the second transistor 500 in that the second conductivity type transistor 400b includes the semiconductor layer 214.

The semiconductor layer 214 may control (e.g., reduce) a threshold voltage of the second conductivity type transistor 400b, which is the PMOS transistor. For example, the semiconductor layer 214 may include or be formed of a semiconductor material different from a semiconductor material of the first substrate 210, or may have a composition or a structure different from a composition or a structure of the substrate 210. For example, the semiconductor layer 214 may include or be formed of germanium, silicon-germanium, or so on, and may have an epitaxial structure. However, the embodiments are not limited thereto, and a material of the semiconductor layer 214 may be variously modified.

In embodiments, the semiconductor layer 214 may be additionally or separately disposed on the first substrate 210, a property of the first substrate 210 may be improved. In a comparative example in which a portion corresponding to the semiconductor layer 214 is disposed in a first substrate, dislocation may be generated and a property of the first substrate may be deteriorated.

In the second conductivity type transistor 400b, the second intermediate layer 320b disposed between the first gate insulation layer 412 and the gate electrode 314 may control or adjust a work function and control (e.g. reduce) a threshold voltage of the second conductivity type transistor 400b. In embodiments, at least a portion of the second intermediate layer 320b may act as a kind of a gate insulation layer together with the first gate insulation layer 412, and/or may act as a kind of a gate electrode together with the gate electrode 314. For example, the second intermediate layer 320b may be referred to as a buffer layer, a buffer electrode layer, a work function control layer, a work function layer, an insertion layer, or so on.

In embodiments, the second intermediate layer 320b may have a stacking structure or a thickness different from a stacking structure or a thickness of the first intermediate layer 320a. The phrase that the first intermediate layer 320a and the second intermediate layer 320b have different stacking structures may refer to a case that a number of a layer or layers included in the first intermediate layer 320a is different from a number of a layer or layers included in the second intermediate layer 320b, a layer including a material that is not included in the first intermediate layer 320a is included in the second intermediate layer 320b, a layer including a material that is not included in the second intermediate layer 320b is included in the first intermediate layer 320a, at least one layer of a plurality of layers that are included in the first intermediate layer 320a is not included in the second intermediate layer 320b, or at least one layer of a plurality of layers that are included in the second intermediate layer 320b is not included in the first intermediate layer 320a.

In embodiments, the second intermediate layer 320b may have a stacking structure different from a stacking structure of the first intermediate layer 320a, and may include the second layer 324. For example, the second intermediate layer 320b may not include the first layer 322 and may include the second layer 324. The second intermediate layer 320b may include or be formed of a single layer of the second layer 324 that includes a material same as a material of the second layer 324 included in the first intermediate layer 320a and has a thickness same as a thickness of the second layer 324 included in the first intermediate layer 320a. For example, in the second conductivity type transistor 400b, the second layer 324 may be in contact with the first gate insulation layer 412. However, the embodiments are not limited thereto, and an additional layer may be disposed between the first gate insulation layer 412 and the second layer 324 of the second intermediate layer 320b. For example, in the second conductivity type transistor 400b, the gate electrode 314 may be in contact with the second layer 324, and a structure and a process may be simplified. However, the embodiments are not limited thereto, and an additional layer may be disposed between the second layer 324 and the gate electrode 314.

Unless otherwise described, a description of the second layer 324 included in the first intermediate layer 320a may be applied to the second layer 324 included in the second intermediate layer 320b.

For example, the first layer 322 may be formed in the first conductivity type transistor 400a and the second conductivity type transistor 400b, the first layer 322 may be selectively removed in the second conductivity type transistor 400b, and the second layer 324 may be formed in the first conductivity type transistor 400a and the second conductivity type transistor 400b to form the first conductivity type transistor 400a and the second conductivity type transistor 400b having the above structure.

When the first layer 322 may be removed in the second conductivity type transistor 400b and the first layer 322 may not be included in the second conductivity type transistor 400b as in the above, the first metal included in the first layer 322 may be prevented from diffusing into the first gate insulation layer 412 of the second conductive transistor 400b. Further, influence of changing process conditions for controlling the threshold voltage of the first conductivity type transistor 400a on the threshold voltage of the second conductivity type transistor 400b may be minimized. In the second conductivity type transistor 400b, the threshold voltage may be controlled without having the first layer 322, the first region 322a, the second region 322b, or the partial dipole, and a mobility degradation due to the first layer 322, the first region 322a, the second region 322b, or the partial dipole may be controlled. A doping process (e.g., an ion implantation process) may be not performed to the second intermediate layer 320b of the second conductivity type transistor 400b, and the second intermediate layer 320b of the second conductivity type transistor 400b may have an improved property. Further, a height difference between the first conductivity type transistor 400a and the second conductivity type transistor 400b may be reduced.

On the other hand, in a comparative example, a second layer may be formed in a second conductivity type transistor, and thereafter, a first layer and a second layer may be sequentially formed in a first conductivity type transistor and the second conductivity type transistor to form a first intermediate layer and a second intermediate layer. Thereby, the second intermediate layer may include the second layer, the first layer, and the second layer, and may have a relatively large thickness. Further, even if the second layer is disposed below the first layer, it may be difficult to completely prevent the first metal included in the first layer from reaching a gate insulation layer through the second layer. If an additional layer (e.g., a metal layer) is further formed to prevent the first metal from reaching the gate insulation layer, a manufacturing process may be complicated and a property deterioration due to the additional layer may occur more significantly.

As in the above, in embodiments, the first intermediate layer 320a may include the first layer 322 and the second layer 324, and the second intermediate layer 320b may include the second layer 324 without the first layer 322. Thereby, a thickness of the second intermediate layer 320b may be less than a thickness of the first intermediate layer 320a. When the thickness of the second intermediate layer 320b is less than the thickness of the first intermediate layer 320a, at least a portion of a step or a height difference by the semiconductor layer 214 included in the second conductivity type transistor 400b may be offset.

Thereby, the height difference between the first conductivity type transistor 400a and the second conductivity type transistor 400b may be less than a thickness of the semiconductor layer 214. That is, the height difference between the first conductivity type transistor 400a and the second conductivity type transistor 400b may be a value obtained by subtracting the thickness of the second layer 322 included in the first conductivity type transistor 400a from the thickness of the semiconductor layer 214 included in the second conductivity type transistor 400b. Thereby, the height difference between the first conductivity type transistor 400a and the second conductivity type transistor 400b may be reduced, and a problem that may be induced in an etching process (e.g., over etching or undercut of the first conductivity type transistor 400a having a relatively small height) may be prevented or reduced. For example, the height difference between the first conductivity type transistor 400a and the second conductivity type transistor 400b may be in a range of 10nm or less.

The height difference between the first conductivity type transistor 400a and the second conductivity type transistor 400b having relatively large heights may be reduced. Accordingly, in a semiconductor device (e.g., a flash memory device) including the plurality of transistors 300 having different heights, a problem that may be induced in an etching process may be prevented or reduced.

The second transistor 500 may include a gate structure 310 (e.g., a second gate structure 510) and source and drain regions 300s and 300d. The second gate structure 510 may include the second gate insulation layer 512, the gate electrode 314, the capping layer 316, the spacer 318, and the cover layer 319 disposed on the first substrate 210. That is, the second transistor 500 may not include layers corresponding to the first intermediate layer 320a of the first conductivity type transistor 400a, the second intermediate layer 320b of the second conductivity type transistor 400b, and the semiconductor layer 214. For example, in the second transistor 500, the second gate insulation layer 512 may be in contact with the first substrate 210 and the gate electrode 314, respectively. However, the embodiments are not limited thereto.

In embodiments, the first surface 2101 of the first substrate 210 in a portion in which the second transistor 500 is disposed may be lower than the first surface 2101 of the first substrate 210 in a portion in which the first transistor 400 is disposed. That is, in the thickness direction of the semiconductor device 10 (the Z-axis direction in the drawings), a lower surface of the first gate structure 410 adjacent to the first surface 2101 of the first substrate 210 in a portion in which the first transistor 400 is disposed may be at a first substrate height HS1, and a lower surface of the second gate structure 510 adjacent to the first surface 2101 of the first substrate 210 in a portion in which the second transistor 500 is disposed may be at a second substrate height HS2, which is lower than the first second substrate height HS1. Thereby, the second transistor 500 including the second gate insulation layer 512 with a relatively large thickness may be easily formed. However, the embodiments are not limited thereto, and the first surface 2101 of the first substrate 210 in a portion in which the second transistor 500 is disposed may be disposed on a same plane as the first surface 2101 of the first substrate 210 in a portion in which the first transistor 400 is disposed. Other various modified embodiments are possible.

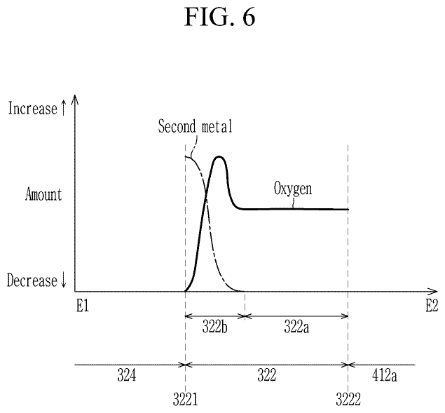

Referring to FIG. 5 and FIG. 6, an example of a partial dipole that may be induced or generated by the second region 322b, which is a dipole induction layer, will be described in detail.

FIG. 5 is an enlarged cross-sectional view of an example of a portion D in FIG. 4. FIG. 6 is a graph schematically illustrating an example of amounts of second metal and oxygen in a direction E in FIG. 5. A left enlarged circle in FIG. 5 mainly illustrates an arrangement of the first region 322a and the second region 322b, and a right enlarged circle in FIG. 5 mainly illustrates a partial dipole induced in the first layer 322. In FIG. 6, it is illustrated as an example that the second layer 324 does not include the second metal, and maximum amounts of the second metal and the oxygen are illustrated to be same for relative comparison.

Referring to FIG. 5 and FIG. 6, when there is a tendency to displace or expel the oxygen in the second region 322b including the second metal due to a difference between the oxygen areal density of the first metal and the oxygen areal density of the second metal, the oxygen included in the first layer 322 may move to be spaced apart from the first surface 3221 of the first layer 322. Thereby, holes may be disposed in a portion adjacent to the first surface 3221 of the first layer 322, and electrons may be disposed in a portion spaced apart from the first surface 3221 of the first layer 322. Accordingly, a first dipole DP1 may be induced or generated.

For a clear understanding, in a right circle in FIG. 5, it is illustrated as an example that the first dipole DP1 is disposed to correspond to the second region 322b. However, the embodiments are not limited thereto, and the first dipole DP1 may be disposed to correspond to a portion of the second region 322b, or may be disposed to correspond to the second region 322b and a portion of the first region 322a.

For a clear understanding, in FIG. 6, it is illustrated as an example that an oxygen-amount change region in which an amount of the oxygen is changed is disposed to correspond to the second region 322b and an isolation region in which the amount of the oxygen is uniform is disposed to correspond to the first region 322a. However, the embodiments are not limited thereto. In some embodiments, the oxygen-amount change region may be disposed to correspond to a portion of the second region 322b, or may be disposed to correspond to the second region 322b and a portion of the first region 322a. In some embodiments, the isolation region may be disposed to correspond to a portion of the first region 322a, or may be disposed to correspond to the first region 322a and a portion of the second region 322b.

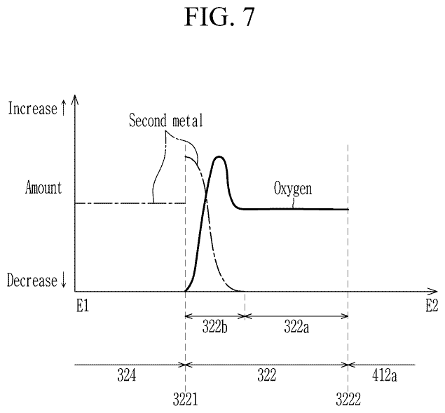

In a modified embodiment, when the second layer 324 may include the second metal, an amount of the second metal may be discontinuous at an interface or a boundary (e.g., the first surface 3221 of the first layer 322) between the first layer 322 and the second layer 324, as illustrated in FIG. 7. In FIG. 7, it is illustrated as an example that a maximum amount of the second metal in the first layer 322 is greater than an amount of the second metal in the second layer 324. However, the embodiments are not limited thereto, and a maximum amount of the second metal in the first layer 322 may be less than an amount of the second metal in the second layer 324.

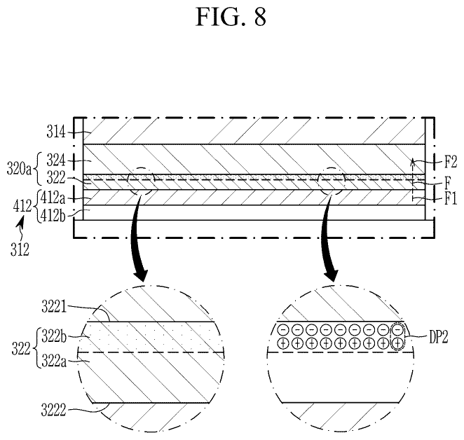

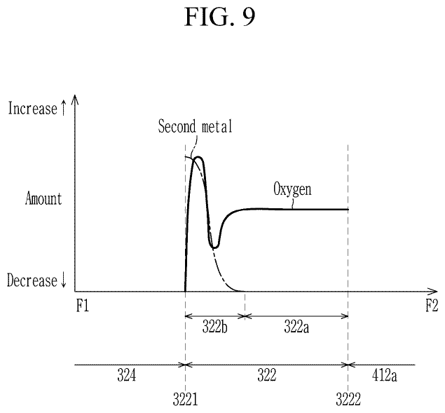

Referring to FIG. 8 and FIG. 9, an example of a partial dipole that may be induced or generated by the second region 322b, which is a dipole induction layer, will be described in detail.

FIG. 8 is an enlarged cross-sectional view of an example of a portion D in FIG. 4. FIG. 9 is a graph schematically illustrating amounts of second metal and oxygen in a direction F in FIG. 8. A left enlarged circle in FIG. 8 mainly illustrates an arrangement of the first region 322a and the second region 322b, and a right enlarged circle in FIG. 8 mainly illustrates a partial dipole induced in the first layer 322. In FIG. 9, it is illustrated as an example that the second layer 324 does not include the second metal, and maximum amounts of the second metal and the oxygen are illustrated to be same for relative comparison.

Referring to FIG. 8 and FIG. 9, when there is a tendency to attract the oxygen in the second region 322b including the second metal due to a difference between the oxygen areal density of the first metal and the oxygen areal density of the second metal, the oxygen included in the first layer 322 may move toward the first surface 3221 of the first layer 322. Thereby, electrons may be disposed in a portion adjacent to the first surface 3221 of the first layer 322, and holes may be disposed in a portion spaced apart from the first surface 3221 of the first layer 322. Accordingly, a second dipole DP2 may be induced or generated.

For a clear understanding, in a right circle in FIG. 8, it is illustrated as an example that the second dipole DP2 is disposed to correspond to the second region 322b. However, the embodiments are not limited thereto, and the second dipole DP2 may be disposed to correspond to a portion of the second region 322b, or may be disposed to correspond to the second region 322b and a portion of the first region 322a.

For a clear understanding, in FIG. 9, it is illustrated as an example that an oxygen-amount change region in which an amount of the oxygen is changed is disposed to correspond to the second region 322b and an isolation region in which the amount of the oxygen is uniform is disposed to correspond to the first region 322a. However, the embodiments are not limited thereto. In some embodiments, the oxygen-amount change region may be disposed to correspond to a portion of the second region 322b, or may be disposed to correspond to the second region 322b and a portion of the first region 322a. In some embodiments, the isolation region may be disposed to correspond to a portion of the first region 322a, or may be disposed to correspond to the first region 322a and a portion of the second region 322b.

In a modified embodiment, when the second layer 324 may include the second metal, an amount of the second metal may be discontinuous at an interface or a boundary (e.g., the first surface 3221 of the first layer 322) between the first layer 322 and the second layer 324.

According to embodiments, the first layer 322 of the first intermediate layer 320a may include the second region 322b including the second metal, and the threshold voltage of the first conductivity type transistor 400a, which is the NMOS transistor, may be reduced. The second region 322b may be spaced apart from the first gate insulation layer 412 while interposing the first region 322a therebetween, and a process of forming the second region 322b or the second metal may be prevented from affecting the first gate insulation layer 412. The second intermediate layer 320b may include the second layer 324 without the first layer 322, and the threshold voltage of the second conductivity type transistor 400b, which is the PMOS transistor, may be reduced, and the height difference between the plurality of transistors 300 may be reduced and a margin in an etching process may be improved. Thereby, performance and reliability of the plurality of transistors 300 may be improved, and performance and reliability of the semiconductor device 10 may be improved.

For a clear understanding, in the drawings, it is illustrated as an example that one first conductivity type transistor 400a is included, one second conductivity type transistor 400b is included, and a plurality of second transistors 500 having a same height are included. However, the embodiments are not limited thereto. For example, a plurality of first conductivity type transistors 400a having different heights, a plurality of second conductivity type transistors 400b having different heights, and/or a plurality of second transistors 500 having different heights may be included.

In the above description, it is described as an example that the semiconductor device 10 includes the cell region 100 and the circuit region 200, but the circuit region 200 including the plurality of transistors 300, the transistor 300, or so on may be referred to as a semiconductor device.

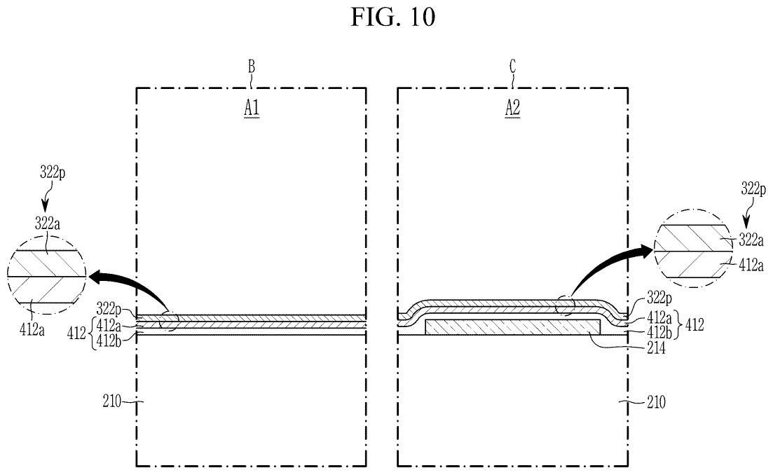

A manufacturing method of a semiconductor device will be described in detail with reference to FIG. 10 to FIG. 14 together with FIG. 1 to FIG. 9. To the extent that an element is not described in detail below, it may be understood that the element is at least substantially similar (and/or the same as) to a corresponding element that has been described elsewhere within the present disclosure. A portion which is not described in the above will be described in detail.

FIG. 10 to FIG. 14 are cross-sectional views illustrating a manufacturing method of a semiconductor device according to embodiments. FIG. 10 to FIG. 14 illustrate a portion corresponding to FIG. 4. Hereinafter, a manufacturing method of a plurality of transistors (e.g., first gate structures 410 of first and second conductivity type transistors 400a and 400b) included in a semiconductor device is mainly described. For a clear understanding, FIG. 10 to FIG. 14 illustrate a first transistor region A1 in which the first conductivity type transistor 400a is disposed and a second transistor region A2 in which the second conductivity type transistor 400b is disposed.

As illustrated in FIG. 10, a semiconductor layer 214, a first gate insulation layer 412, and a preliminary layer 322p including a first region 322a may be formed on a first substrate 210.

The semiconductor layer 214 may include or be formed of a semiconductor material different from a material of the first substrate 210.

The semiconductor layer 214 may be formed in a second transistor region A2. The semiconductor layer 214 may be partially formed to correspond to the second transistor region A2 by any of various methods. For example, the semiconductor layer 214 may be entirely formed, and a patterning process of the semiconductor layer 214 may be performed such that the semiconductor layer 214 corresponds to the second transistor region A2. The process of forming the semiconductor layer 214 may be performed by any of various processes (e.g., a deposition process), and the patterning process of the semiconductor layer 214 may be performed by any of various processes (e.g., a photolithography process, an etching process, or so on).

It is described as an example that the first gate insulation layer 412 includes an interfacial layer 412b and a high dielectric constant insulation layer 412a, but the embodiments are not limited thereto. The first region 322a or the preliminary layer 322p may include first metal and oxygen. For example, the first region 322a or the preliminary layer 322p may include or be formed of an oxide layer or an oxynitride layer including the first metal and the oxygen. In a thickness direction, the entirety of the preliminary layer 322p may be formed of the first region 322a.

The first gate insulation layer 412 and the preliminary layer 322p may be formed to be entirely disposed on the first substrate 210 and the semiconductor layer 214. Accordingly, the first gate insulation layer 412 and the preliminary layer 322p may be formed in first and second transistor regions A1 and A2. The preliminary layer 322p may be a first layer formed on the first gate insulation layer 412. For example, in the first and second transistor regions A1 and A2, the preliminary layer 322p may be in contact with the first gate insulation layer 412. However, the embodiments are not limited thereto.

The first gate insulation layer 412 and the preliminary layer 322p may be formed by any of various processes (e.g., a deposition process or so on).

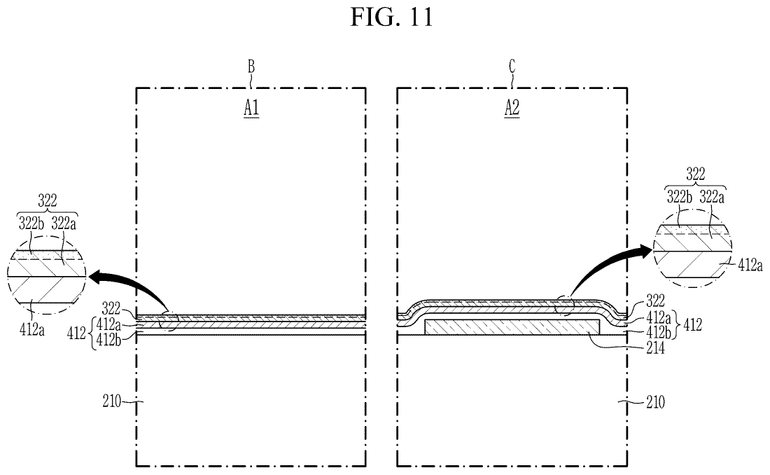

Subsequently, as illustrated in FIG. 11, a doping process of the second metal may be performed in a portion (e.g., an upper portion) of the preliminary layer 322p (refer to FIG. 10) in a thickness direction, and a second region 322b may be formed in the portion (e.g., the upper portion) of the preliminary layer 322p. The first region 322a may be remained below the second region 322b. Thereby, a first layer 322 including the first region 322a and the second region 322b may be formed.

The doping process of the second metal may be performed by any of various processes (e.g., an ion implantation process or so on). For example, the ion implantation process of the second metal may be a material modification implantation (MMI) process. When the doping process of the second metal may be performed by the ion implantation process, the second region 322b may be stably formed in a shallow region corresponding to a portion of the preliminary layer 322p in the thickness direction.

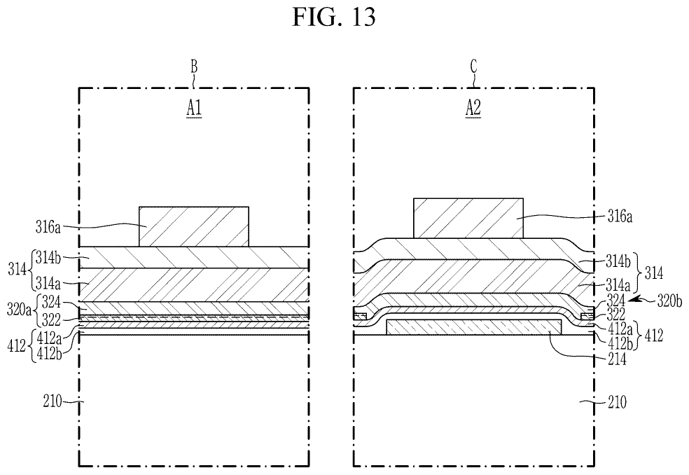

In embodiments, in the doping process of the second metal, the doping process of the second metal may be performed in a portion of the first layer 322 in a state that the first layer 322 is exposed to an outside. Thereby, in the thickness direction, the doping process of the second metal for forming the second region 322b in the shallow region corresponding to a portion of the preliminary layer 322p may be easily performed. Accordingly, an undesirable property deterioration of the first gate insulation layer 412 (e.g., the high dielectric constant insulation layer 412a) and a second layer 324 (refer to FIG. 13) that will be formed later may be prevented or reduced.

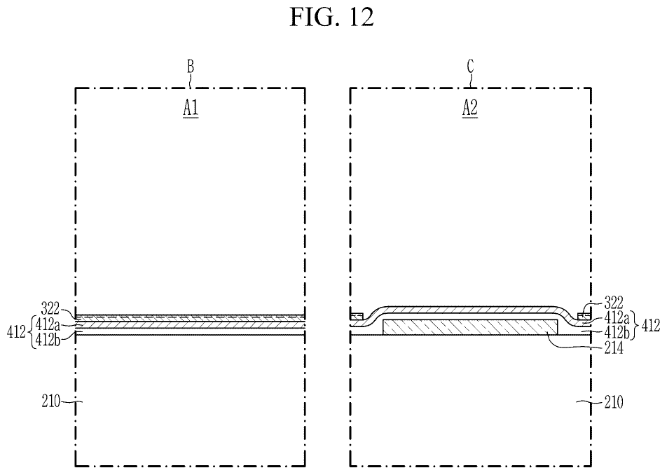

Subsequently, as illustrated in FIG. 12, a portion of the first layer 322 in the second transistor region A2 may be removed. The process of removing a portion of the first layer 322 may be performed using any of various processes (e.g., a photolithography process, an etching process, or so on). For example, the process of removing the portion of the first layer 322 may be performed using a wet etching process, but the embodiments are not limited thereto.

Subsequently, as illustrated in FIG. 13, a second layer 324, a gate electrode 314, and a first capping layer 316a may be formed the first gate insulation layer 412 and the first layer 322.

The second layer 324 and the gate electrode 314 may be formed to be entirely disposed on the first gate insulation layer 412 and the first layer 322. Accordingly, the second layer 324 and the gate electrode 314 may be formed in the first and second transistor regions A1 and A2.

The second layer 324 and the gate electrode 314 may be formed on the first layer 322 in the first transistor region A1, and the second layer 324 and the gate electrode 314 may be formed on the first gate insulation layer 412 without the first layer 322 in the second transistor region A2. It is illustrated as an example that the gate electrode 314 includes a first electrode layer 314a and a second electrode layer 314b, but the embodiments are not limited thereto.

The processes of forming the second layer 324 and the gate electrode 314 may be performed by any of various processes (e.g., a deposition process).

The first capping layer 316a may be formed on the gate electrode 314. For example, the first capping layer 316a may be entirely formed, and a patterning process of the first capping layer 316a may be performed such that the first capping layer 316a corresponds to each of the first and second transistor regions A1 and A2. The process of forming the first capping layer 316a may be performed by any of various processes (e.g., a deposition process), and the patterning process of the first capping layer 316a may be performed by any of various processes (e.g., a photolithography process, an etching process, or so on).

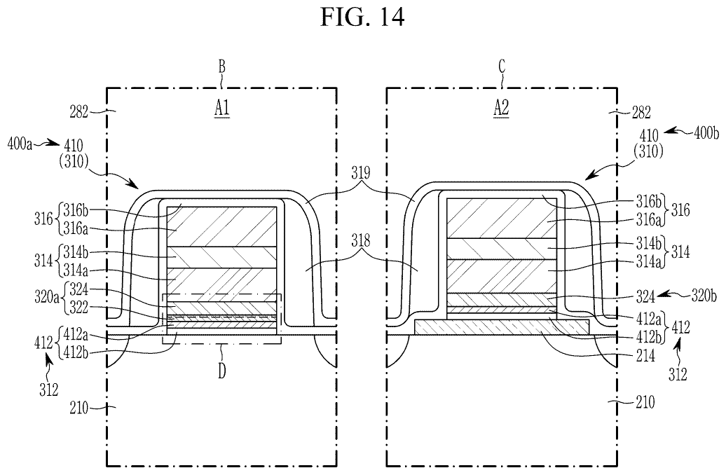

Subsequently, as illustrated in FIG. 14, a patterning process of the first gate insulation layer 412, the first layer 322, the second layer 324, the gate electrode 314 may be performed using the first capping layer 316a as a mask, and a second capping layer 316b, a spacer 318, and a cover layer 319 may be sequentially formed.

Thereby, in the first transistor region A1, a first gate structure 410 of a first conductivity type transistor 400a including the first gate insulation layer 412, the first intermediate layer 320a, the gate electrode 314, the capping layer 316, the spacer 318, and the cover layer 319 may be formed. In the second transistor region A2, a first gate structure 410 of a second conductivity type transistor 400b including the first gate insulation layer 412, the second intermediate layer 320b, the gate electrode 314, the capping layer 316, the spacer 318 and the cover layer 319 may be formed. The first intermediate layer 320a may include the first layer 322 and the second layer 324, and the second intermediate layer 320b may include the second layer 324.

The patterning process using the first capping layer 316a as the mask may be performed by any of various processes (e.g., an etching process or so on).

The second capping layer 316b may be formed to be entirely disposed on a side surface and/or an upper surface of the first substrate 210, the semiconductor layer 214, the first gate insulation layer 412, the first and second intermediate layers 320a and 320b, the gate electrode 314, and the first capping layer 316a. The process of forming the second capping layer 316b may be performed by any of various processes (e.g., a deposition process).

The spacer 318 may be formed by any of various methods. For example, a preliminary spacer layer may be entirely formed, and a patterning process of the preliminary spacer layer may be formed to form the spacer 318. The process of forming the preliminary spacer layer may be performed by any of various processes (e.g., a deposition process), and the patterning process of the preliminary spacer layer may be performed by any of various processes (e.g., a photolithography process, an etching process, or so on).

Source and drain regions 300s and 300d (refer to FIG. 3) may be formed using the spacer 318 as a mask. The process of forming the source and drain regions 300s and 300d may be performed by any of various doping processes (e.g., an ion implantation process).

The cover layer 319 may be formed to be entirely disposed on the first substrate 210, the semiconductor layer 214, the first gate insulation layer 412, the first and second intermediate layers 320a and 320b, the gate electrode 314, the capping layer 316, and the spacer 318. The process of forming the cover layer 319 may be performed by any of various processes (e.g., a deposition process).

In embodiments, a device isolator 212 (refer to FIG. 3) may be formed in a plurality of processes of forming a plurality of gate structure 310 included in a plurality of transistors 300, or before or after one process of the plurality of processes. An order of the process of forming the device isolator 212 may be variously modified. The process of forming the device isolator 212 may be performed by any of various processes. For example, the device isolator 212 may be formed by forming a trench using an etching process performed at a first surface of the first substrate 210 and filling an insulating material in the trench.

Subsequently, a first wiring portion 280 (refer to FIG. 1) electrically connected to the first and second conductivity type transistors 400a and 400b may be formed.

According to embodiments, in the first and second conductivity type transistors 400a and 400b, the first layer 322 may be formed on the first gate insulation layer 412 and thereafter a portion of the first layer 322 corresponding to the second conductivity type transistor 400b may be removed. Thus, the second conductivity type transistor 400b may not include the first layer 322. Accordingly, the first layer 322 including the second region 322b may be included in the first conductivity type transistor 400a, and a threshold voltage of the first conductivity type transistor 400a may be reduced. Further, in the second conductivity type transistor 400b, the first metal or so on included in the first layer 322 may be prevented from diffusing to the first gate insulation layer 412 (e.g., the high dielectric constant insulation layer 412a), and a threshold voltage of the second conductivity type transistor 400b may be reduced. In the second conductivity type transistor 400b, a second layer may not be disposed below the first layer 322, and a process may be simplified, and a height difference between the first and second conductivity type transistors 400a and 400b may be reduced and a problem that may induced in an etching process (e.g., over etching or undercut of the first conductivity type transistor 400a having a relatively small height) may be prevented or reduced. Thereby, a margin in an etching process may be improved.

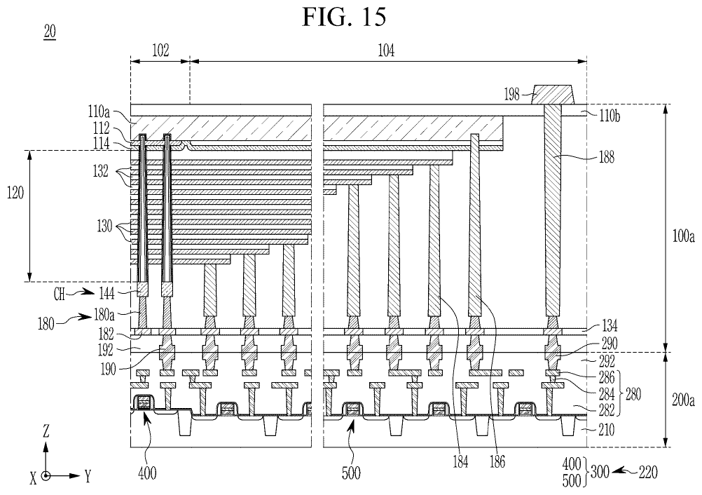

Hereinafter, referring to FIG. 15, a semiconductor device 20 according to embodiments will be described in detail. To the extent that an element is not described in detail below, it may be understood that the element is at least substantially similar (and/or the same as) to a corresponding element that has been described elsewhere within the present disclosure. A portion which is not described in the above will be described in detail.

FIG. 15 is a cross-sectional view schematically illustrating a semiconductor device 20 according to embodiments.

Referring to FIG. 15, a semiconductor device 20 according to embodiments may be a bonding semiconductor device in which a cell region 100a may be separately formed from a circuit region 200a and be bonded to the circuit region 200a. For example, the cell region 100a may be bonded to the circuit region 200a by hybrid bonding, such as, a chip to chip (C2C) bonding process, a chip-to-wafer bonding process, or a wafer-to-wafer bonding process.

The circuit region 200a may include a first substrate 210, a circuit element 220, a first wiring portion 280, and a first bonding structure 290 electrically connected to the first wiring portion 280 at a surface facing the cell region 100a. A region other than the first bonding structure 290 at the surface facing the cell region 100a may be covered by a first bonding insulation layer 292.

The cell region 100a may include a second substrate 110a, a gate stacking structure 120, a channel structure CH, a second wiring portion 180, and a second bonding structure 190 electrically connected the second wiring portion 180 at a surface facing the circuit region 200a. A region other than the second bonding structure 190 may be covered by a second bonding insulation layer 192 at the surface facing the circuit region 200a.

In embodiments, the second substrate 110a may be a semiconductor substrate including a semiconductor material. For example, the second substrate 110a may include a semiconductor layer including or formed of silicon, germanium, silicon-germanium, or so on. In some embodiments, the second substrate 110a may further include an insulation layer. That is, after the cell region 100a may be bonded to the circuit region 200a, the second substrate 110a may be removed and an additional layer may be formed.

In embodiments, the gate stacking structure 120 may be sequentially stacked on a lower portion of the second substrate 110a in the drawing, and may have a structure in which a gate stacking structure 120 illustrated in FIG. 1 is disposed in a vertically inverted manner. The channel structure CH passing through or penetrating the gate stacking structure 120 may have a structure in which a channel structure CH illustrated in FIG. 2 is disposed in a vertically inverted manner. Accordingly, in a cross-sectional view, the channel structure CH may have an inclined side surface such that a width of the channel structure CH decreases from the circuit region 200a toward the second substrate 110a. A channel pad 144 and the second wiring portion 180 on the gate stacking structure 120 may be adjacent to the circuit region 200a.

For example, the first bonding structure 290 and/or the second bonding structure 190 may include aluminum, copper, tungsten, or an alloy including the same. For example, the first and second bonding structures 290 and 190 may include or be formed of copper so that the cell region 100a and the circuit region 200a may be bonded (e.g., directly bonded) to each other by copper-to-copper bonding.

In FIG. 15, it is illustrated as an example that the gate stacking structure 120 includes one gate stacking portion. In some embodiment, the gate stacking structure 120 may include a plurality of gate stacking portions. Unless otherwise described, the description of the gate stacking structure 120 and the channel structure CH with reference to FIG. 1 and FIG. 2 may be applied to the gate stacking structure 120 and the channel structure CH. In FIG. 15, it is illustrated as an example that an electrical connection structure of the channel structure CH with horizontal conductive layers 112 and 114 and/or the second substrate 110a is the same as an electrical connection structure of the channel structure CH with the horizontal conductive layers 112 and 114 and/or the second substrate 110 in FIG. 1. The embodiments are not limited thereto, and the electrical connection structure of the channel structure CH with the horizontal conductive layers 112 and 114 and/or the second substrate 110a may be variously modified.

The semiconductor device 20 according to embodiments may include an input/output pad 198, and a through plug 188 or an input/output connection wiring electrically connected to the input/output pad 198. The through plug 188 or the input/output connection wiring may be electrically connected to a part of the second bonding structures 190. For example, the input/output pad 198 may be on an insulation layer 110b covering an outer surface of the second substrate 110a. In some embodiments, an additional input/output pad electrically connected to the circuit region 200a may be provided.

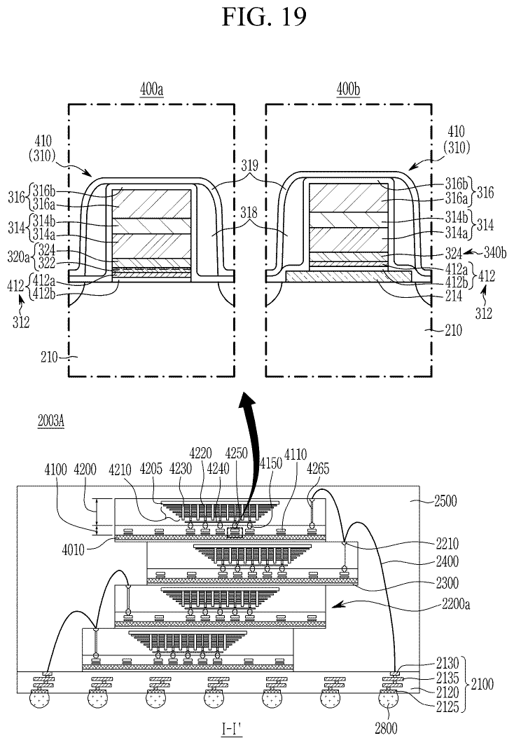

For example, the circuit region 200a and the cell region 100a may be portions corresponding to a first structure 1100F and a second structure 1100S of a semiconductor device 1100 included in an electronic system 1000 illustrated in FIG. 16, respectively. For example, the circuit region 200a and the cell region 100a may be regions including a first structure 4100 and a second structure 4200 of a semiconductor device 2200a illustrated in FIG. 19, respectively.

Hereinafter, an example of an electronic system that includes a semiconductor device described in the above will be described in detail.

FIG. 16 schematically illustrates an electronic system that includes a semiconductor device according to embodiments.

Referring to FIG. 16, an electronic system 1000 according to embodiments may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 15. The semiconductor device 1100 may include a first structure 1100F and a second structure 1100S that is disposed on the first structure 1100F. In embodiments, the first structure 1100F may be next to the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to embodiments.

In embodiments, the lower transistor LT1 or LT2 may include a ground selection transistor, and the upper transistor UT1 or UT2 may include a string selection transistor. The first and second gate lower lines LL1 and LL2 may be gate electrode layers of the lower transistors LT1 and LT2, respectively. The word line WL may be a gate electrode layer of the memory cell transistor MCT, and the gate upper lines UL1 and UL2 may be gate electrode layers of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or so on may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

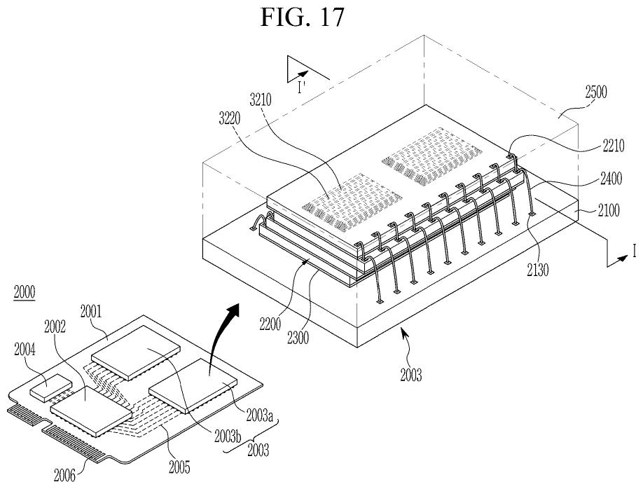

FIG. 17 is a perspective view schematically illustrating an electronic system including a semiconductor device according to embodiments.

Referring to FIG. 17, an electronic system 2000 according to embodiments may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In embodiments, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In embodiments, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may a semiconductor package including a plurality of semiconductor devices 2200. Each of the first and second semiconductor packages 2003a and 2003b may include a package substrate 2100, the semiconductor device 2200 that is disposed on the package substrate 2100, an adhesive layer 2300 at a lower surface of each semiconductor device 2200, a connection structure 2400 that electrically connects the semiconductor device 2200 and the package substrate 2100, and a molding layer 2500 that covers the semiconductor device 2200 and the connection structure 2400 on the package substrate 2100.

The package substrate 2100 may be a printed circuit board that includes a package upper pad 2130. Each semiconductor device 2200 may include an input/output pad 2210. The input/output pad 2210 may correspond to an input/output pad 1101 of FIG. 16. Each semiconductor device 2200 may include a gate stacking structure 3210 and a channel structure 3220. The semiconductor device 2200 may include a semiconductor device described with reference to FIG. 1 to FIG. 15.

In embodiments, the connection structure 2400 may be a bonding wire that electrically connects the input/output pad 2210 and the package upper pad 2130. Accordingly, in each of the first and second semiconductor packages 2003a and 2003b, the semiconductor devices 2200 may be electrically connected to each other using a bonding wire type, and the semiconductor device 2200 may be electrically connected to the package upper pad 2130 of the package substrate 2100. In some embodiments, in each of the first and second semiconductor packages 2003a and 2003b, the semiconductor devices 2200 may be electrically connected to each other by a connection structure that includes a through silicon via (TSV) instead of the connection structure 2400 of the bonding wire type.

In embodiments, the controller 2002 and the semiconductor device 2200 may be included in one package. For example, the controller 2002 and the semiconductor device 2200 may be mounted on a separate interposer substrate that is different from the main substrate 2001, and the controller 2002 and the semiconductor device 2200 may be connected to each other by a wiring of the interposer substrate.

FIG. 18 and FIG. 19 are cross-sectional views schematically illustrating semiconductor packages according to embodiments, respectively. FIG. 18 and FIG. 19 respectively illustrate embodiments of the semiconductor package 2003 of FIG. 17, and conceptually illustrate a region obtained by cutting the semiconductor package 2003 of FIG. 17 along a line I-I′.

Referring to FIG. 18, in a semiconductor package 2003, a package substrate 2100 may be a printed circuit board. The package substrate 2100 may include a package substrate body portion 2120, a package upper pad 2130 that is disposed at an upper surface of the package substrate body portion 2120, a package lower pad 2125 that is disposed at a lower surface of the package substrate body portion 2120 or is exposed through the lower surface of the package substrate body portion 2120, and an internal wiring 2135 that electrically connects the package upper pad 2130 and the package lower pad 2125 inside the package substrate body portion 2120. The package upper pad 2130 may be electrically connected to the connection structure 2400. The package lower pad 2125 may be connected to a wiring pattern 2005 of a main substrate 2001 of an electronic system 2000, as illustrated in FIG. 17, through a conductive connection portion 2600.

The semiconductor device 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 on the common source line 3205, a channel structure 3220 and a separation structure 3230 passing through the gate stacking structure 3210, a bit line 3240 electrically connected to the channel structure 3220, and a gate connection wiring electrically connected to a word line WL (refer to FIG. 16) of the gate stacking structure 3210.

In the semiconductor device 2200 according to embodiments, performance and reliability of a plurality of transistors may be improved by first and second intermediate layers and performance and reliability of a semiconductor device may be improved.

Each of the semiconductor devices 2200 may include a through wiring 3245 that is electrically connected to a peripheral wiring 3110 of the first structure 3100 and extends into the second structure 3200. The through wiring 3245 may pass through the gate stacking structure 3210, and may be further provided at an outside of the gate stacking structure 3210. Each semiconductor device 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In embodiments, in the semiconductor package 2003, a plurality of semiconductor devices 2200 may be electrically connected to each other by a connection structure 2400 having a bonding wire type. In some embodiments, the plurality of semiconductor devices 2200 or a plurality of portions constituting the plurality of semiconductor devices 2200 may be electrically connected by a connection structure including a through silicon via (TSV).

Referring to FIG. 19, in a semiconductor package 2003A, each semiconductor device 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region that includes a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 that pass through the gate stacking structure 4210, and a second bonding structures 4250 that are electrically connected to the channel structure 4220 and a word line WL (refer to FIG. 16) of the gate stacking structure 4210. For example, the second bonding structure 4250 may be electrically connected to the channel structure 4220 and the word line WL through a bit line 4240 that is electrically connected to the channel structure 4220 and a gate connection wiring that is electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In the semiconductor device 2200a according to embodiments, performance and reliability of a plurality of transistors may be improved by first and second intermediate layers and performance and reliability of a semiconductor device may be improved.

Each of the semiconductor devices 2200a may further include an input/output pad 2210 and an input/output connection wiring 4265 that is disposed at a lower portion of the input/output pad 2210. The input/output connection wiring 4265 may be electrically connected to a part of the second bonding structures 4250.

In embodiments, in the semiconductor package 2003A, a plurality of semiconductor devices 2200a may be electrically connected to each other by a connection structure 2400 having a bonding wire type. In some embodiments, a plurality of semiconductor devices 2200a may be electrically connected to each other by a connection structure including a through silicon via (TSV).

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. A semiconductor device, comprising:
a substrate; and
a plurality of transistors on or at the substrate,
wherein the plurality of transistors include a first conductivity type transistor,
wherein the first conductivity type transistor includes a gate insulation layer, a first intermediate layer, and a gate electrode sequentially on the substrate,
wherein the first intermediate layer includes a first region including a first metal on the gate insulation layer and a second region spaced apart from the gate insulation layer on the first region, and wherein the second region includes the first metal, and a second metal different from the first metal.

2. The semiconductor device of claim 1, wherein the first conductivity type transistor has a high dielectric constant metal gate (high-K metal gate, HKMG) structure.

3. The semiconductor device of claim 1, wherein the first region includes the first metal and oxygen, and
wherein the second metal has an oxygen areal density different from an oxygen areal density of the first metal.

4. The semiconductor device of claim 1, wherein the second metal includes at least one of a group 2 element, a transition metal, a group 13element, a group 14 element, and a group 15 element.

5. The semiconductor device of claim 4, wherein the second metal includes at least one of strontium, yttrium, titanium, zirconium, hafnium, niobium, and germanium.

6. The semiconductor device of claim 1, wherein a thickness of the first region is greater than a thickness of the second region.

7. The semiconductor device of claim 1, wherein the first intermediate layer includes a first layer and a second layer on the first layer, and
wherein the first layer includes the first region and the second region,
wherein the second layer has a work function greater than a work function of the first region.

8. The semiconductor device of claim 7, wherein the second metal is different from a metal included in the second layer, or
wherein an amount of the second metal in the second region is different from an amount of the second metal in the second layer.

9. The semiconductor device of claim 1, wherein the plurality of transistors include a second conductivity type transistor,
wherein the second conductivity type transistor includes a semiconductor layer, a gate insulation layer, a second intermediate layer, and a gate electrode,
wherein the semiconductor layer of the second conductivity type transistor is on the substrate and includes a material different from a material of the substrate,
wherein the gate insulation layer of the second conductivity type transistor is on the semiconductor layer of the second conductivity type transistor,
wherein the second intermediate layer is on the gate insulation layer of the second conductivity type transistor and has a stacking structure different from a stacking structure of the first intermediate layer, and wherein the gate electrode of the second conductivity type transistor is on the second intermediate layer.

10. The semiconductor device of claim 9, wherein the first intermediate layer includes a first layer and a second layer on the first layer,
wherein the first layer includes the first region and the second region,
wherein the second layer has a work function different from a work function of the first region, and
wherein the second intermediate layer has a stacking structure different from a stacking structure of the first intermediate layer and includes the second layer.

11. The semiconductor device of claim 9, wherein the first intermediate layer includes a first layer and a second layer on the first layer,
wherein the first layer includes the first region and the second region,
wherein the second layer has a work function different from a work function of the first region, and
wherein the second intermediate layer is a single layer of the second layer.

12. The semiconductor device of claim 9, wherein a thickness of the second intermediate layer is less than a thickness of the first intermediate layer.

13. The semiconductor device of claim 9, wherein a height difference between the first conductivity type transistor and the second conductivity type transistor is less than a thickness of the semiconductor layer.

14. The semiconductor device of claim 9, wherein a height difference between the first conductivity type transistor and the second conductivity type transistor is in a range of 10 nm or less.

15. A semiconductor device, comprising:
a substrate; and
a plurality of transistors on or at the substrate,
wherein the plurality of transistors include a first conductivity type transistor,
wherein the first conductivity type transistor includes a gate insulation layer, a first intermediate layer, and a gate electrode sequentially on the substrate,
wherein the first intermediate layer includes a first layer and a second layer sequentially on the gate insulation layer and including different materials,
wherein the first layer includes an oxygen-amount change region in which an oxygen amount changes, and
wherein, in a thickness direction of the first layer, the oxygen-amount change region is partially disposed in the first layer to be adjacent to a first surface of the first layer that is adjacent to the second layer and to be spaced apart from the gate insulation layer.

16. The semiconductor device of claim 15, wherein the first layer includes an isolation region in which an oxygen amount is uniform, and
wherein the isolation region is adjacent to a second surface of the first layer adjacent to the gate insulation layer in the thickness direction of the first layer.

17. The semiconductor device of claim 15, wherein the first conductivity type transistor is an n-type metal-oxide semiconductor (NMOS) transistor, and
wherein the first layer includes an n-type work function layer, and the second layer includes a p-type work function layer.

18. The semiconductor device of claim 15, wherein the plurality of transistors include a second conductivity type transistor,
wherein the second conductivity type transistor includes a semiconductor layer, a gate insulation layer, a second intermediate layer, and a gate electrode,
wherein the semiconductor layer of the second conductivity type transistor is on the substrate and includes a material different from a material of the substrate,
wherein the gate insulation layer of the second conductivity type transistor is on the semiconductor layer of the second conductivity type transistor,
wherein the second intermediate layer is on the gate insulation layer of the second conductivity type transistor and has a stacking structure different from a stacking structure of the first intermediate layer, and
wherein the gate electrode of the second conductivity type transistor is on the second intermediate layer.

19. The semiconductor device of claim 18, wherein the second intermediate layer has a stacking structure different from a stacking structure of the first intermediate layer and includes the second layer.

20. An electronic system, comprising:
a main substrate;
a semiconductor device on the main substrate; and
a controller electrically connected to the semiconductor device on the main substrate,
wherein the semiconductor device includes a substrate and a plurality of transistors on or at the substrate,
wherein the plurality of transistors include a first conductivity type transistor,
wherein the first conductivity type transistor includes a gate insulation layer, a first intermediate layer, and a gate electrode sequentially on the substrate,
wherein the first intermediate layer includes a first region including a first metal on the gate insulation layer and a second region spaced apart from the gate insulation layer on the first region, and
wherein the second region includes the first metal, and a second metal different from the first metal.
